(19) United States
(12) Patent Application Publication
(10) Pub. No.: US 2026/0036805 A1
(43) Pub. Date: Feb. 5, 2026

(54) MICROELECTROMECHANICAL SYSTEM DEVICE WITH ELONGATED VIA

(71) Applicant: TEXAS INSTRUMENTS INCORPORATED, Dallas, TX (US)

(72) Inventors: Sean C. O'BRIEN, Dallas, TX (US); William C. MCDONALD, Allen, TX (US)

(21) Appl. No.: 18/789,336

(22) Filed: Jul. 30, 2024

(51) Int. Cl. G02B 26/08; B81B 3/00

(52) U.S. Cl. CPC G02B 26/0841; B81B 3/0062; B81B 2201/042

(57) ABSTRACT

A microelectromechanical system (MEMS) device includes: a hinge layer; a second layer; and an elongated via coupled between the hinge layer and the second layer.

### BACKGROUND

There are some microelectromechanical system (MEMS) device applications, where a reduction in the size of a MEMS device is desirable. For example, the resolution, or number of pixels, of a display system may be increased with reduced size MEMS devices. However, MEMS device size reduction may cause layout, spacing, and fabrication issues.

### SUMMARY

In an example, a microelectromechanical system (MEMS) device includes: a hinge layer; a second layer; and an elongated via coupled between the hinge layer and the second layer.

In another example, a MEMS device includes: a mirror layer; an electrode layer; a hinge layer; a mirror via coupling the mirror layer and the hinge layer; and an elongated via coupling the hinge layer and the electrode layer.

In yet another example, a MEMS device includes: a mirror layer; an electrode layer comprising a first electrode and a second electrode spaced from the first electrode; a hinge layer including a hinge; an elongated via coupling the hinge and the mirror layer; and a hinge via coupling the hinge and the first electrode.

### BRIEF DESCRIPTION OF THE DRAWINGS

FIG. 1A is an exploded view of a microelectromechanical system (MEMS) device in accordance with various examples.

FIG. 1B is a perspective view of the MEMS device of FIG. 1A.

FIG. 2A is an exploded view of a MEMS device in accordance with various examples.

FIG. 2B is a perspective view of the MEMS device of FIG. 2A.

FIG. 2C is a first cross-sectional view of the MEMS device of FIG. 2A.

FIG. 2D is a second cross-sectional view of the MEMS device of FIG. 2A.

FIG. 2E is a see through top view of the MEMS device of FIG. 2A.

FIG. 3 is a top view showing an elongated via shape relative to a symmetrical via shape in accordance with various examples.

FIGS. 4 to 6 are see-through top views of MEMS device components in accordance with various examples.

FIGS. 7 to 10 are perspective views of other MEMS devices in accordance with various examples.

FIG. 11 is a flowchart showing a MEMS device fabrication method in accordance with various examples.

FIG. 12 is a flowchart showing another MEMS device fabrication method in accordance with various examples.

FIGS. 13A to 13M are cross-sectional views of MEMS device fabrication steps in accordance with various examples.

### DETAILED DESCRIPTION

The same reference numbers or other reference designators are used in the drawings to designate the same or similar features. Such features may be the same or similar either by function and/or structure.

Described herein are microelectromechanical system (MEMS) devices with layers and with one or more elongated (asymmetrical) vias coupling two of the layers. Example layers include an electrode layer, a hinge layer, and a moving element(s) layer. In such examples, one or more elongated via may couple the hinge layer to the moving element(s) layer. Additionally, or alternatively, one or more elongated via may couple the hinge layer to the electrode layer.

In some examples, each elongated via is a three-dimensional shape (e.g., a cylinder or rectangular prism) of conductive material with an axis and an outer surface. The three-dimensional shape may be defined by a width, a length, and a height. In some examples, each elongated via is a hollow three-dimensional shape (e.g., a hollow cylinder or hollow rectangular prism) of conductive material. In some examples, each elongated via is an open and hollow three-dimensional shape (e.g., an open and hollow cylinder or an open and hollow rectangular prism) of conductive material. For elongated vias that are hollow, the thickness of the conductive material may vary.

A cross-section perpendicular to the axis of an elongated via (i.e., a cross-section taken at a particular height of the elongated via) shows a cross-sectional (top view) shape and thickness of the related conductive material. In some examples, the conductive material of an elongated via may have a cross-sectional shape that is an oval or ellipse. In other examples, the conductive material of an elongated via may have cross-sectional shape that is a rectangle or a rounded rectangle. In different examples, the orientation of elongation of an elongated via may vary. In other words, the width of an elongated via may be greater than the length of the elongated via, or the width of an elongated via may be less than the length of the elongated via. The dimensions of each elongated via may vary and may be selected to facilitate layout, spacing, and/or miniaturization of a particular MEMS device or related product. Without limitation, a MEMS device with one or more elongated vias may be used to form a pixel of a spatial light modulator (SLM) or a phase light modulator (PLM) of a display system. Example pixel sizes that may benefit from a MEMS device with one or more elongated vias include 6 um pixels, 5.5 um pixels, 5.0 um pixels, 4.5 um pixels, 4.0 um pixels, 3.6 um pixels, 2.7 um pixels, or smaller pixels.

Each elongated via described herein, or groups of elongated vias, may vary with regard to orientation to adjust the spacing between a MEMS device via and other MEMS device components along a target direction or in a target zone. The target direction or target zone may be selected, for example, based on hinge layer layout, an electrode layer layout, a moving element layer layout, via layouts, a combination of such layouts, and/or fabrication testing results. In some examples, one or more elongated vias may be used to increase the spacing between a hinge via and an electrode, a related raised electrode, or related electrode vias (e.g., the hinge via and/or the electrode vias may be elongated vias oriented to increase the spacing therebetween). As another example, one or more elongated vias may be used to increase the spacing between a spring tip via and an electrode, a related raised electrode, or related electrode vias (e.g., the spring tip via and/or the electrode vias may be elongated vias oriented to increase the spacing therebetween). As another example, one or more elongated vias may be used to increase the spacing between a mirror via and an electrode or related electrode via (e.g., the mirror via and/or the electrode vias may be elongated vias oriented to increase the spacing therebetween). For different MEMS device sizes, different MEMS device types (e.g., torsion hinge with two spring tips, torsion hinge with four spring tips, cantilever hinge with one spring tip) and different layouts of related MEMS device layers/components, the amount of elongation (e.g., the aspect ratio of an elongated via), the orientation of elongation, the thickness of via walls, and/or other elongated via parameters may vary for each elongated via or groups of elongated vias. Use of one or more elongated vias can increase the spacing between adjacent MEMS device components to facilitate miniaturization efforts and/or account for the limitations/tolerances of different fabrication options. With elongated vias, the number of MEMS device failures due to contact between adjacent MEMS device components can be reduced without significant expense or re-design of MEMS device layer layouts.

In different examples, the orientation of an elongated via may vary based on the layout of adjacent MEMS device components as well as the orientation of a MEMS device relative to other MEMS device (e.g., the orientation of pixels). In some examples, the orientation may be selected to maximize spacing between a target adjacent MEMS device component or to maximize an average spacing between multiple adjacent MEMS device components.

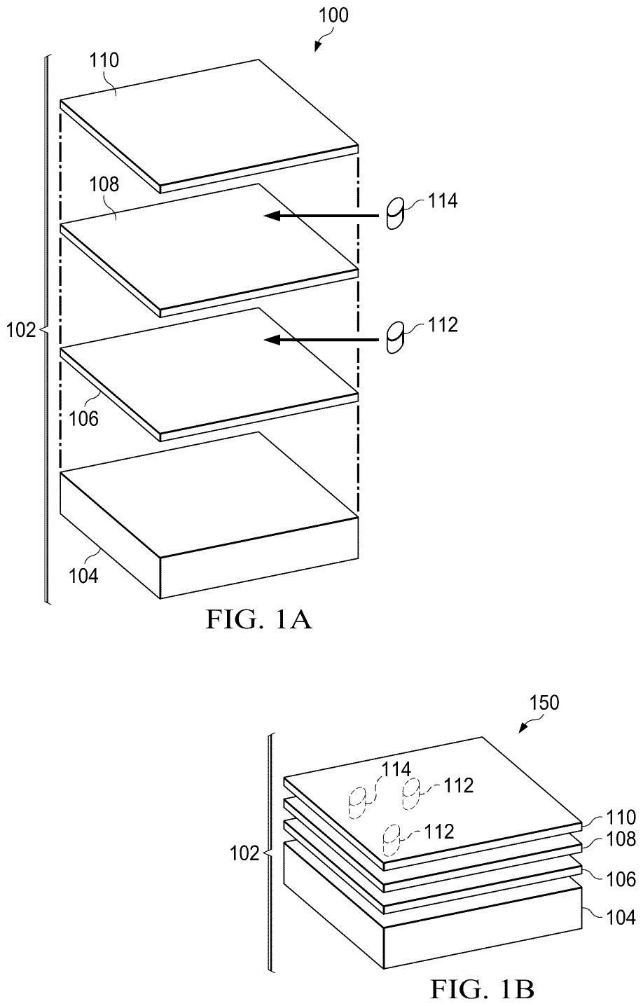

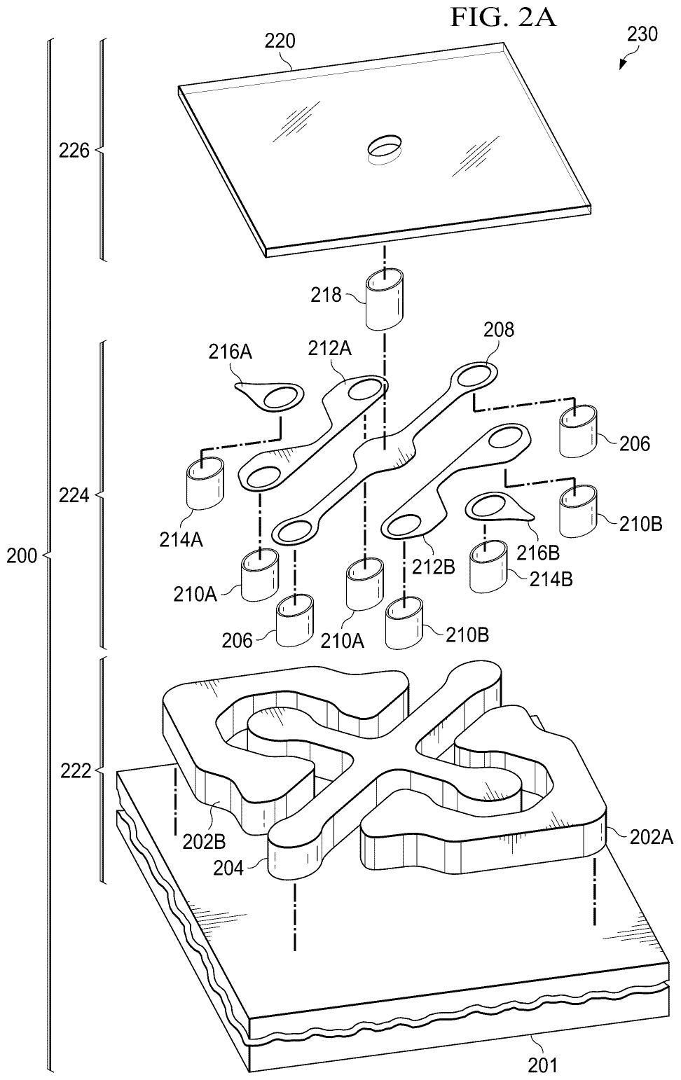

FIG. 1A is an exploded view 100 of a microelectromechanical system (MEMS) device 102 in accordance with various examples. The MEMS device 102 includes a base 104, an electrode layer 106, a hinge layer 108, and a moving element(s) layer 110. The base 104 includes memory cells (not shown) to control different states of the MEMS device 102 responsive to received data. In some examples, the electrode layer 106 includes first and second electrodes coupled to the base 104. In some examples, the hinge layer 108 includes one or more hinges, raised electrodes, spring tips, and/or other components. In some examples, the moving element(s) layer 110 includes a mirror.

In some examples, the elongated via(s) 112 couple the hinge layer 108 to the electrode layer 106. Additionally, or alternatively, the elongated via(s) 114 may couple the hinge layer 108 to the moving element(s) layer 110. In some examples, a MEMS device may include a combination of elongated vias (e.g., the elongated via(s) 112 and/or the elongated via(s) 114) and symmetrical (unelongated) vias.

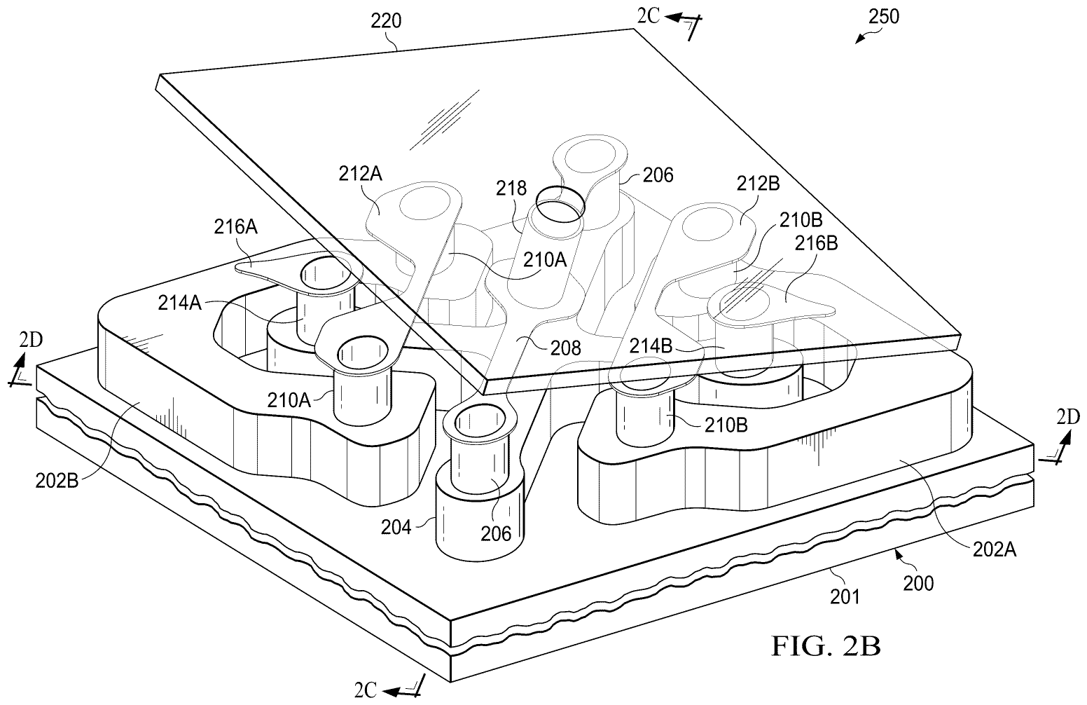

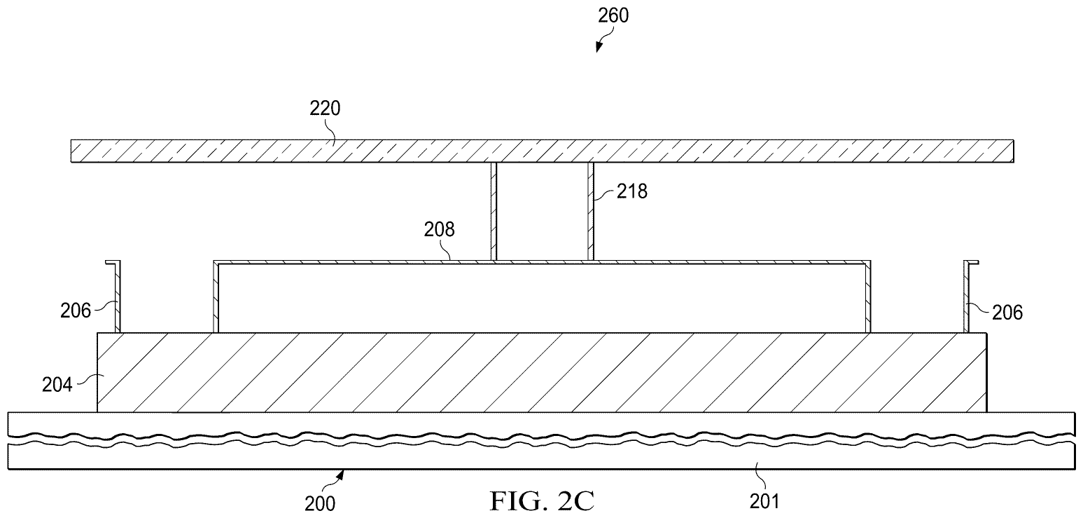

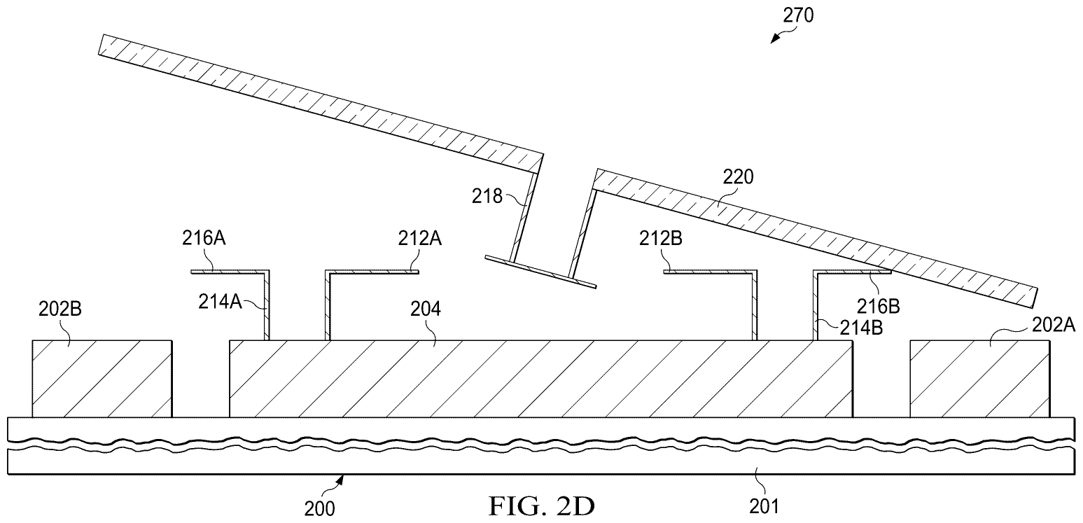

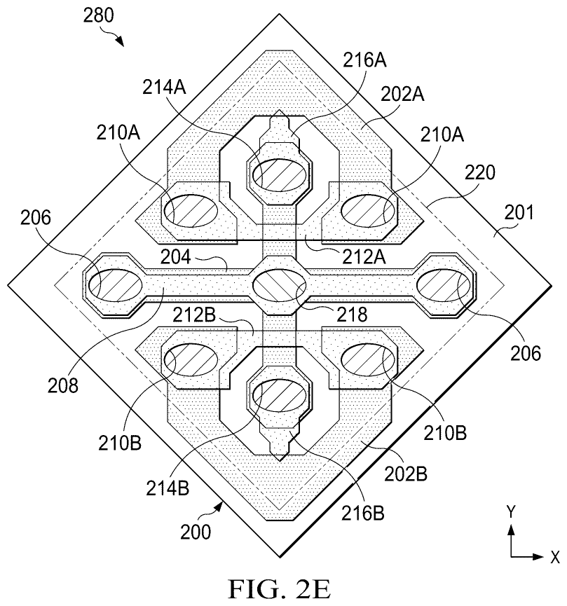

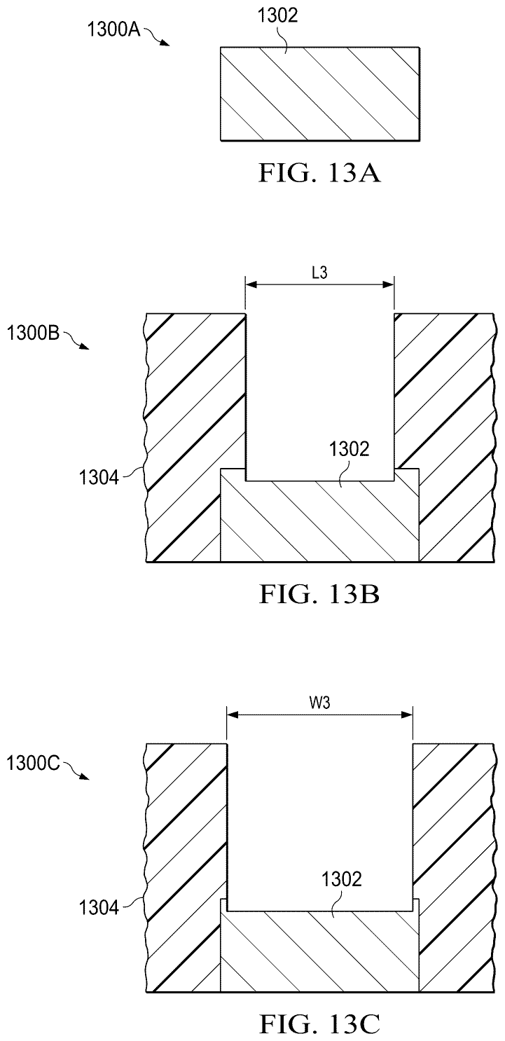

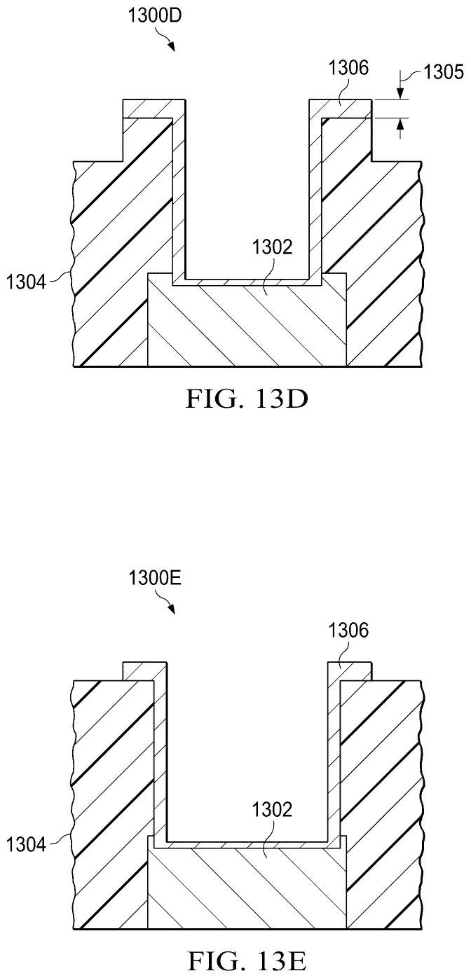

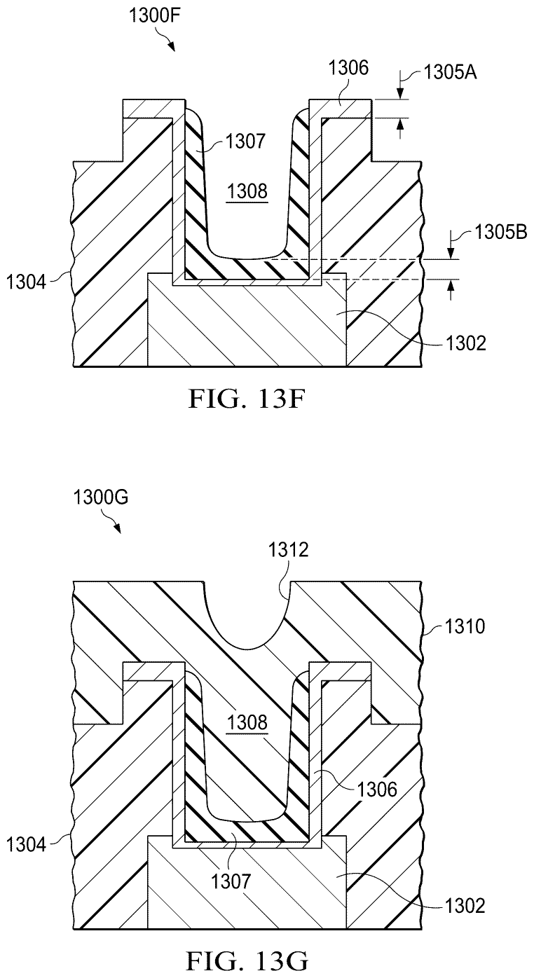

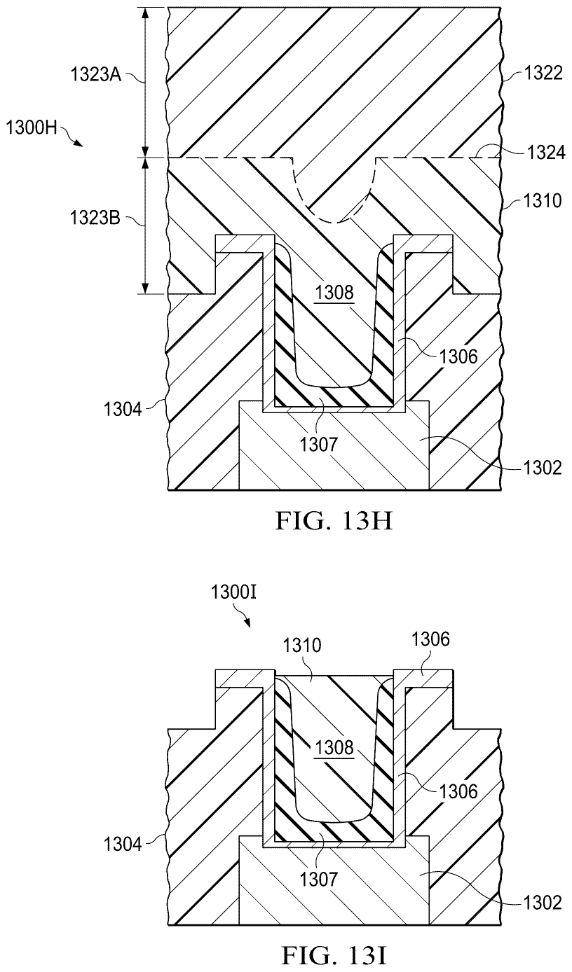

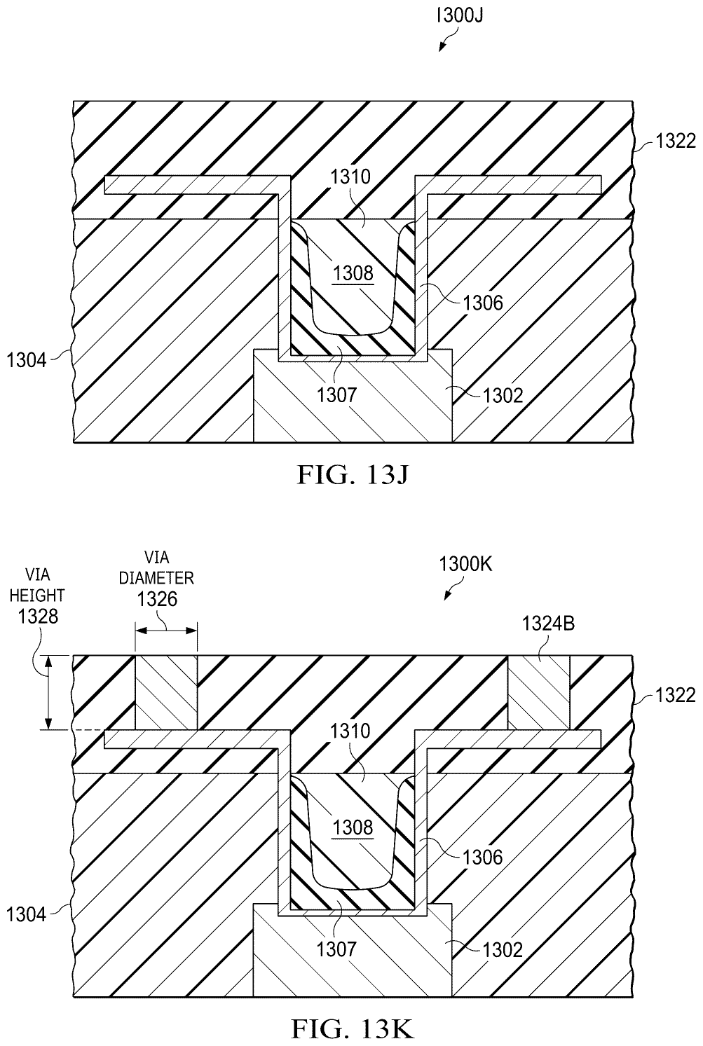

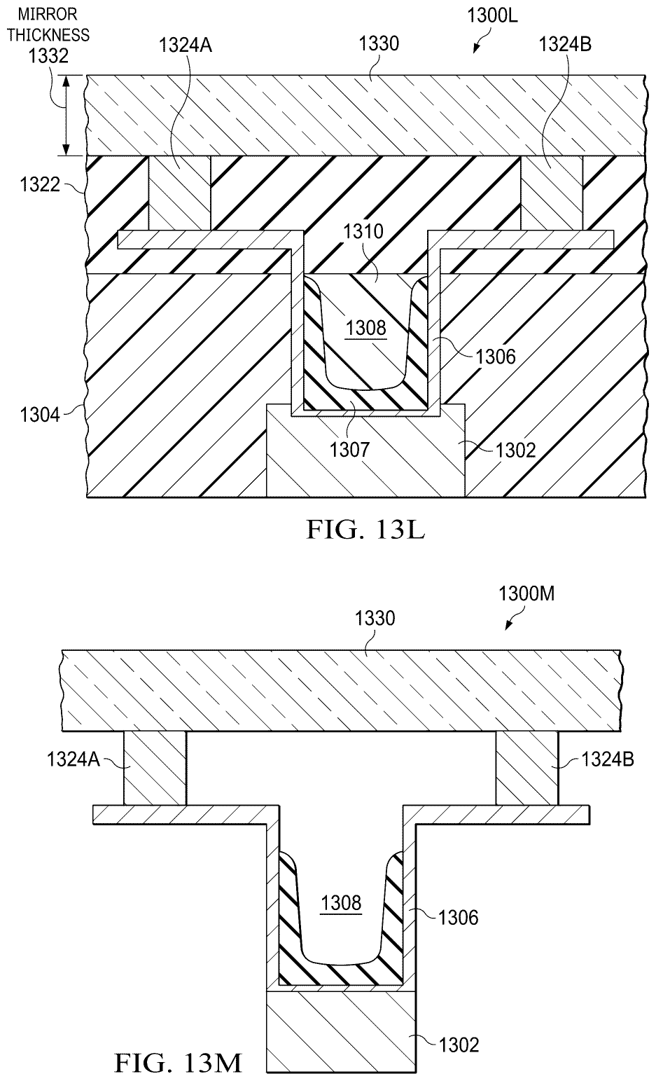

In some examples, the MEMS device 102 may be part of a single spring tip pixel as in FIGS. 2A to 2E. In other examples, the MEMS device 102 may be part of a tilt and roll pixel (TRP) element as in FIG. 13. In other examples, the MEMS device 102 may be part of a dual spring tip pixel as in FIG. 14.

FIG. 1B is a perspective view 150 of the MEMS device 102 of FIG. 1A in accordance with various examples. In the example of FIG. 1B, the MEMS device 102 includes the base 104, the electrode layer 106, the hinge layer 108, and the moving element(s) layer 110 stacked together. In the example of FIG. 1B, elongated via(s) 112 couple the electrode layer 106 and the hinge layer 108. Also, elongated via(s) 114 couple the hinge layer 108 and the moving element(s) layer 110.

In an example SLM, the moving element(s) layer 110 of the MEMS device 102 tilts between two or more positions based on: received data; and operations of the base 104 and the hinge layer 108 responsive to the received data. In an example PLM, the moving element(s) layer 110 of the MEMS device moves up and down between two or more positions based on: received data; and operations of the base 104 and the hinge layer 108 responsive to the received data. In different examples, the number of total vias and the number of elongated vias between the hinge layer 108 and the electrode layer 106 may vary. Similarly, in different examples, the number of total vias and the number of elongated vias between the hinge layer 108 and the moving element(s) layer 110 may vary. The dimensions of each elongated via may vary and may be selected to facilitate layout, spacing, and/or miniaturization of a particular MEMS device or related product. Without limitation, the MEMS device 102 may be used to form a pixel of a SLM or a PLM of a display system. Example pixel sizes that may benefit from the MEMS device 102 and related elongated vias include 6 um pixels, 5.5 um pixels, 5.0 um pixels, 4.5 um pixels, 4.0 um pixels, 3.6 um pixels, 2.7 um pixels, or smaller pixels.

FIGS. 2A to 2E are different views of an example MEMS device 200. FIG. 2A is an exploded view 230 of the MEMS device 200. FIG. 2B is a perspective view 250 of the MEMS device 200. FIG. 2C is a first cross-sectional view 260 of the MEMS device 200. FIG. 2D is a second cross-sectional view 270 of the MEMS device 200. FIG. 2E is a see through top view 280 of the MEMS device 200. In the example of FIG. 2A, the MEMS device 200 is an example of a single spring tip pixel. As shown, the MEMS device 200 includes a base 201, electrode layer 222, hinge vias 206, first electrode vias 210A, second electrode vias 210B, a first spring tip via 214A, a second spring tip via 214B, a hinge layer 224, a mirror via 218, and a mirror layer 226. In the example of FIG. 2A, the base 201 is split to represent its thickness may vary. The base 201 may include memory cells to control different states of the MEMS device 200 responsive to received data. The electrode layer 222 is an example of the electrode layer 106 in FIGS. 1A and 1B. In some examples, the hinge vias 206, the first electrode vias 210A, the second electrode vias 210B, the first spring tip via 214A, and the second spring tip via 214B are examples of the elongated via(s) 112 in FIGS. 1A and 1B. The hinge layer 224 is an example of the hinge layer 108 in FIGS. 1A and 1B. In some examples, the mirror via 218 is an example of the elongated via(s) 114 in FIGS. 1A and 1B. The mirror layer 226 is an example of the moving element(s) layer 110 in FIGS. 1A and 1B.

In the example of FIG. 2A, the hinge vias 206, the first electrode vias 210A, the second electrode vias 210B, the first spring tip via 214A, the second spring tip via 214B, and the mirror via 218 have the same elongated oval shape and orientation. In other examples, the shape, the amount of elongation, and/or the orientation of each or all of the hinge vias 206, the first electrode vias 210A, the second electrode vias 210B, the first spring tip via 214A, the second spring tip via 214B, and the mirror via 218 may vary from the example of FIG. 2A to adjust the spacing between adjacent MEMS device components.

In the example of FIG. 2A, the electrode layer 222 includes a first address electrode 202A, a second address electrode 202B, and a bias electrode 204 spaced from the first and second address electrodes 202A and 202B. In some examples, there are two of the hinge vias 206, two of the first electrode vias 210A, two of the second electrode vias 210B, one first spring tip via 214A, one second spring tip via 214B, and one mirror via 218. In other examples, the number of hinge vias 206, the number of first electrode vias 210A, the number of second electrode vias 210B, the number of first spring tip vias 214A, the number of second spring tip vias 214B, and/or the number of mirror vias 218 may vary. In the example of FIG. 2A, each of the hinge vias 206, each of the first electrode vias 210A, each of the second electrode vias 210B, the first spring tip via 214A, the second spring tip via 214B, and the mirror via 218 are elongated vias. In other examples, one or more of the hinge vias 206, the first electrode vias 210A, the second electrode vias 210B, the first spring tip via 214A, the second spring tip via 214B, and the mirror via 218 may be a symmetrical via while others of the hinge vias 206, the first electrode vias 210A, the second electrode vias 210B, the first spring tip via 214A, the second spring tip via 214B, and the mirror via 218 are elongated vias.

In the example of FIG. 2A, the hinge layer 224 includes a torsion hinge 208, a first raised electrode 212A, a second raised electrode 212B, a first spring tip 216A, and a second spring tip 216B. In other examples, the hinge layer 224 may include multiple torsion hinges 208, multiple first raised electrodes 212A, multiple second raised electrodes 212B, multiple first spring tips 216A, and/or multiple second spring tips 216B. In the example of FIG. 2A, the mirror layer 226 includes a mirror 220. In other examples, the mirror layer 226 may include multiple mirrors 220.

FIG. 2B is a perspective view 250 of the MEMS device 200 of FIG. 2A. In the example of FIG. 2B, the base 201, the components of the electrode layer 222, the components of the hinge layer 224, the hinge vias 206, the first electrode vias 210A, the second electrode vias 210B, the first spring tip via 214A, the second spring tip via 214B, the mirror via 218, and components of the mirror layer 226 are close together. In the example of FIG. 2B, the base 201 is split to represent its thickness may vary. As shown, the position of the mirror 220 is tilted. In an example SLM, the position of the mirror 220 switches between different tilted positions responsive to: received data; control voltages applied to the first address electrode 202A, the second address electrode 202B, and the bias electrode 204 responsive to received data; and movement of the torsion hinge 208 and mirror 220 responsive to application of the control voltages.

In the example of FIG. 2B, the mirror 220 is in a first position, in which the mirror 220 contacts the second spring tip 216B responsive to control voltages applied to the first address electrode 202A, the second address electrode 202B, and the bias electrode 204. To change the position of the mirror 220 to another position (e.g., with the mirror 220 contacting the first spring tip 216A), updated control voltages are applied to the first address electrode 202A, the second address electrode 202B, and/or the bias electrode 204.

In different examples, the number of total vias and the number of elongated vias between the hinge layer 224 and the electrode layer 222 may vary. Similarly, in different examples, the number of total vias and the number of elongated vias between the hinge layer 224 and the mirror layer 226 may vary. The dimensions of each elongated via may vary and may be selected to facilitate layout, spacing, and/or miniaturization of a particular MEMS device or related product. Without limitation, the MEMS device 200 may be used to form a pixel of a SLM of a display system. Example pixel sizes that may benefit from the MEMS device 200 and related elongated via(s) include 6 um pixels, 5.5 um pixels, 5.0 um pixels, 4.5 um pixels, 4.0 um pixels, 3.6 um pixels, 2.7 um pixels, or smaller pixels.

FIG. 2C is a first cross-sectional view 260 of the MEMS device 200 of FIG. 2A. In the first cross-sectional view 260, part of the mirror 220, part of the mirror via 218, part of the hinge vias 206, part of the torsion hinge 208, part of the first electrode vias 210A, part of the first spring tip via 214A, and part of the base 201 are visible. In the example of FIG. 2C, the base 201 is split to represent its thickness may vary.

FIG. 2D is a second cross-sectional view 270 of the MEMS device 200 of FIG. 2A. In the second cross-sectional view 270, part of the mirror 220, part of the mirror via 218, part of the first spring tip via 214A, part of the first spring tip 216A, part of one of the first electrode vias 210A, part of the first raised electrode 212A, part of one of the hinge vias 206, part of the second spring tip via 214B, part of the second spring tip 216B, part of one of the second electrode vias 210B, part of the first raised electrode 212A, part of the second raised electrode 212B, part of the first address electrode 202A, part of the second address electrode 202B, part of the bias electrode 204, and part of the base 201 are visible. In the example of FIG. 2D, the base 201 is split to represent its thickness may vary.

FIG. 2E is a see through top view 280 of the MEMS device 200 of FIG. 2A. In the see through top view 280, the relative position, size, and spacing of the base 201, the first address electrode 202A, the second address electrode 202B, the bias electrode 204, the hinge vias 206, the torsion hinge 208, the first electrode vias 210A, the first raised electrode 212A, the first spring tip via 214A, the first spring tip 216A, the second electrode vias 210B, the second raised electrode 212B, the second spring tip via 214B, the second spring tip 216B, and the mirror via 218 are shown. In the example of FIG. 2E, each of the hinge vias 206, each of the first electrode vias 210A, each of the second electrode vias 210B, the first spring tip via 214A, the second spring tip via 214B, and the mirror via 218 are elongated vias. In other examples, one or more of the hinge vias 206, the first electrode vias 210A, the second electrode vias 210B, the first spring tip via 214A, the second spring tip via 214B, and the mirror via 218 may be a symmetrical via while others of the hinge vias 206, the first electrode vias 210A, the second electrode vias 210B, the first spring tip via 214A, the second spring tip via 214B, and the mirror via 218 are elongated vias. In one example, only the mirror via 218 is an elongated via, while the hinge vias 206, the first electrode vias 210A, the second electrode vias 210B, the first spring tip via 214A, and the second spring tip via 214B are symmetric vias. In another example, only the first spring tip via 214A and the second spring tip via 214B are elongated vias, while the hinge vias 206, the first electrode vias 210A, the second electrode vias 210B, and the mirror via 218 are symmetric vias. In another example, mirror via 218, the first spring tip via 214A, and the second spring tip via 214B are elongated vias, while the hinge vias 206, the first electrode vias 210A, and the second electrode vias 210B are symmetric vias. Other combinations of elongated vias and symmetric vias are possible as well.

In the example of FIG. 2E, the hinge vias 206, the first electrode vias 210A, the second electrode vias 210B, the first spring tip via 214A, the second spring tip via 214B, and the mirror via 218 have the same elongated oval shape and orientation. In the example of FIG. 2E, the elongated oval shape has a length (in the X direction) and width (in the Y direction), where the length is greater than the width. Compared to a symmetric via shape (e.g., a circle), the elongated oval shape may have a reduced width or may be compressed in the Y direction to increase spacing between hinge layer components in the Y direction. Compared to a symmetric via shape (e.g., a circle), the elongated oval shape may have the same length or an increased length in the X direction to support a target via wall thickness and related conductivity. With vias compressed in the Y direction, the spacing between the first raised electrode 212A, the torsion hinge 208, the mirror via 218, and/or the second raised electrode 212B in the Y direction is suitable for miniaturization efforts or relaxed fabrication tolerances for the MEMS device 200. With vias maintained or enlarged in the X direction, miniaturization efforts of the MEMS device 200 do not negatively affect the via wall thickness and related conductivity.

In other examples, the shape, the amount of elongation, and/or the orientation of each or all of the hinge vias 206, the first electrode vias 210A, the second electrode vias 210B, the first spring tip via 214A, the second spring tip via 214B, and the mirror via 218 may vary from the example of FIG. 2E to adjust the spacing between adjacent MEMS device components. With elongated vias, the spacing between vias and adjacent elements of an electrode layer (e.g., the electrode layer 222), a hinge layer (e.g., the hinge layer 224) may be increased in at least one dimension to facilitate layout, spacing, and/or miniaturization of a particular MEMS device or related product.

If the example of FIGS. 2A to 2E is for a 2.7 um mirror pitch, the width of each elongated via may be 0.3 um, and the length of each elongated via may be 0.45 um. In contrast, each symmetric via for a 2.7 um mirror pitch may have a width of 0.35 um, and the length of 0.35 um. For a 2.7 um mirror pitch with elongated vias, the spacing between a hinge center pad (e.g., the hinge material around the mirror via 218) and an adjacent raised electrode may be 0.15 um (compared to 0.025 um with symmetric vias only). Also, the spacing between a spring tip and an adjacent raised electrode may be 0.175 um (compared to 0.025 um with symmetric vias only). In the elongated via example given, the aspect ratio of elongation is 0.45:0.30 (or 1.5). In other examples, the aspect ratio of elongation may be greater than 1.5. In different examples, the aspect ratio and/or dimensions of elongated vias may vary depending on the mirror pitch, the MEMS device design, and/or fabrication tolerances. In some examples, the mirror via 218 is spaced from a first side of the first raised electrode 212A by 0.125 um up to 0.15 um, and the first spring tip via 214A is spaced from a second side of the first raised electrode 212A by 0.15 um up to 0.175 um. In some examples, the mirror via 218 is spaced from a first side of the second raised electrode 212B by 0.125 um up to 0.15 um, and the second spring tip via 214B is spaced from a second side of the second raised electrode 212B by 0.15 um up to 0.175 um.

In some examples, the fabrication of a MEMS device begins with a completed memory circuit. The memory circuitry may be, for example, a complementary metal-oxide semiconductor (CMOS) memory circuit. Through the use of photomask layers, the MEMS device superstructure is formed with alternating layers of aluminum or other metal for electrode layer components, hinge layer components, and mirror layer components. In different examples, the aluminum or other metal may be sputter-deposited and plasma-etched. Hardened photoresist is used for sacrificial layers to form air gaps of a MEMS device. The sacrificial layers may be plasma-etched.

During fabrication, there is a chemical-physical challenge to sputtering metal atoms onto a first vertical edge (e.g., a first side of a via coupling a lower MEMS device surface to a MEMS device higher surface). A very simplistic description is that sputtered metal atoms move vertically (from above a wafer downwards) with no horizontal motion. Accordingly, metal atoms do not effectively coat a vertical surface. A second vertical surface (e.g., a second side of the via coupling the lower MEMS device surface to the higher MEMS device surface) will also need to be coated with atoms, and there are only so many atoms to share. If two vertical surfaces are sufficiently spaced from each other, independent sputtering operations can be used to coat the two vertical surfaces. Otherwise, if the vertical surfaces are not sufficiently spaced from each other, metal atoms during sputtering operations are shared between the two sides. For an elongated via with two sides closer together, and two sides further apart, the sides that are closer together will have thinner metal thickness. While expensive lithography tools can print smaller MEMS device components, use of elongated vias enables use of available and less expensive lithography tools to reduce MEMS device dimensions (e.g., the distance from the edge of the via to the edge of hinge layer components).

In the example of FIG. 2E, the first and second address electrodes 202A and 202B extend beyond the outline of the mirror 220. In such examples, the first and second address electrodes 202A and 202B may extend partially (e.g., halfway or less) into the gap between mirrors. In other examples, the first and second address electrodes 202A and 202B do not extend beyond the outline of the mirror 220.

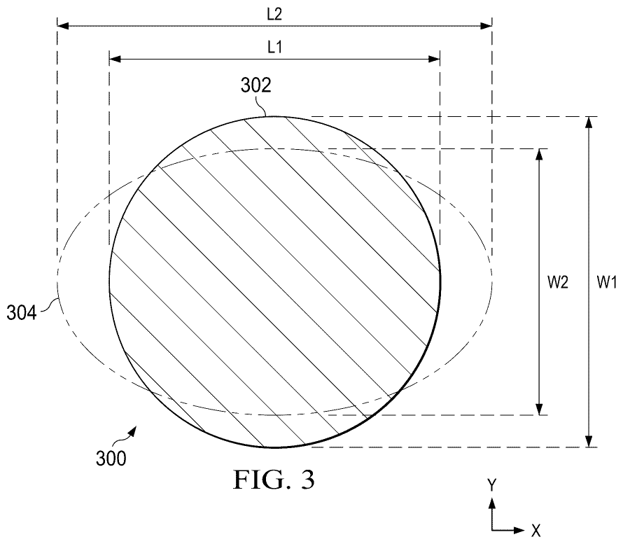

FIG. 3 is a diagram 300 showing an elongated via shape 304 relative to a symmetrical via shape 302 in accordance with various examples. The elongated via shape 304 is visible from a top view or a cross-section of an elongated via such as the hinge vias 206, the first electrode vias 210A, the second electrode vias 210B, the first spring tip via 214A, the second spring tip via 214B, and the mirror via 218 in FIGS. 2A to 2E. In the example of FIG. 3, the symmetrical via shape 302 is a circle shape with a length L1 in the X direction and a width W1 in the Y direction (i.e., a radius of L/2 or W/2). The elongated via shape 304 is an oval or elliptical shape with a length L2 in the X direction and a width W2 in the Y direction. In some examples, the length L1 of the symmetrical via shape 302 is less than the length L2 of the elongated via shape 304. In some examples, the width W1 of the symmetrical via shape 302 is greater than the width W2 of the elongated via shape 304. In other examples, the width W2 of the elongated via shape 304 may be greater than the width W1 of the symmetrical via shape 302, and the length L2 of the of the elongated via shape 304 may be less than the length L1 of the symmetrical via shape 302 (or the elongated via shape 304 may be rotated 90 degrees). In some examples, some vias of a MEMS device may have the symmetrical via shape 302, while other vias of a MEMS device may have the elongated via shape 304. If W1=0.35 um and L1=0.35 um, the area of the symmetric via shape 302 is approximately 0.096 um². If W2=0.3 um and L2=0.45 um, the area of the elongated via shape 304 is approximately 0.106 um². In this example, the area of the elongate via shape 304 is slightly greater than the area of the symmetric via shape 302. In other examples, the dimensions and area of the symmetric via shape 302 and the elongate via shape 304 may vary.

Compared to the symmetric via shape 302, the elongated via shape 304 has a reduced or compressed width (i.e., W2 is less than W1) to increase spacing between hinge layer components and/or electrode layer components in the Y direction. Compared to the symmetric via shape 302, the elongated via shape 304 may have the same length or an increased length (i.e., L2 greater than or equal to L1) to support a target via wall thickness and related conductivity. With vias compressed in a target direction (e.g., the Y direction in FIG. 3), the spacing between a first raised electrode (e.g., the first raised electrode 212A in FIGS. 2A to 2E), a hinge (e.g., the torsion hinge 208 in FIGS. 2A to 2E), a mirror via (e.g., the mirror via 218 in FIGS. 2A to 2E), and/or a second raised electrode (e.g., the second raised electrode 212B) in the Y direction is increased, which facilitates miniaturization efforts of a MEMS device (e.g., the MEMS device 200 related to FIGS. 2A to 2E). With vias maintained or enlarged in the X direction, miniaturization of a MEMS device does not negatively affect the via wall thickness and related conductivity.

In other examples, the symmetrical via shape 302 may have a square or rounded shape and the elongated via shape 304 may have a rectangular or rounded rectangle shape. In different examples, the value of L2 and W2 for the elongated via shape 304 may be adjusted to adjust the amount of elongation and/or the size of an elongated via.

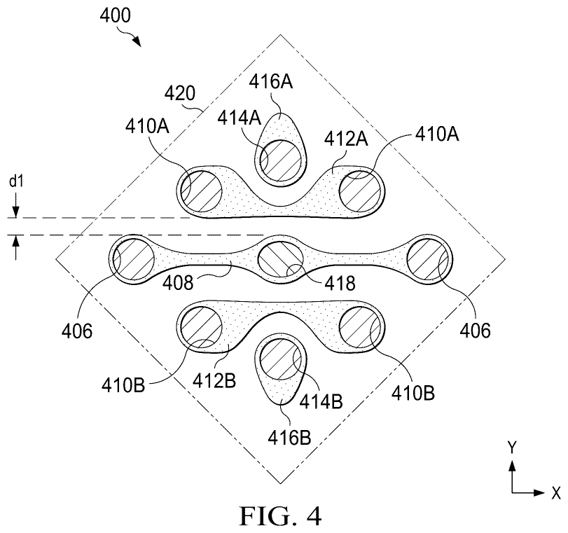

FIG. 4 is a see-through top view 400 of MEMS device components in accordance with various examples. In the see-through top view 400 of FIG. 4, the relative position, size, and spacing of torsion hinge vias 406, a torsion hinge 408, first electrode vias 410A, second electrode vias 410B, a first raised electrode 412A, a second raised electrode 412B, a first spring tip via 414A, a second spring tip via 414B, a first spring tip 416A, a second spring tip 416B, a mirror via 418, and a mirror 420 are shown. The torsion hinge vias 406 are examples of the hinge vias 206 in FIGS. 2A to 2E. The torsion hinge 408 is an example of the torsion hinge 208 in FIGS. 2A to 2E. The first electrode vias 410A are examples of the first electrode vias 210A in FIGS. 2A-2E. The second electrode vias 410B are examples of the second electrode vias 210B in FIGS. 2A-2E. The first raised electrode 412A is an example of the first raised electrode 212A in FIGS. 2A to 2E. The second raised electrode 412B is an example of the second raised electrode 212B in FIGS. 2A to 2E. The first spring tip via 414A is an example of the first spring tip via 214A in FIGS. 2A to 2E. The second spring tip via 414B is an example of the second spring tip via 214B in FIGS. 2A to 2E. The first spring tip 416A is an example of the first spring tip 216A in FIGS. 2A to 2E. The second spring tip 416B is an example of the second spring tip 216B in FIGS. 2A to 2E. The mirror via 418 is an example of the mirror via 218 in FIGS. 2A to 2E. The mirror 420 is an example of the mirror 220 in FIGS. 2A to 2E.

In the example of FIG. 4, only the mirror via 418 is elongated (i.e., the torsion hinge vias 406, the first electrode vias 410A, the second electrode vias 410B, the first spring tip via 414A, and the second spring tip via 414B are symmetric vias), which increases the spacing d1 between the mirror via pad portion of the torsion hinge 408 and the first raised electrode 412A. The spacing between the mirror via pad portion and the second raised electrode 412B is also d1, which may facilitate layout, spacing, and/or miniaturization of a particular MEMS device or related product. In the example of FIG. 4, the mirror via 418 has an elongation orientation parallel to the first and second raised electrodes 412A and 412B so that the spacing d1 is increased relative to a MEMS device design with only symmetric vias. In some examples, use of a limited number of elongated vias (e.g., one elongated via in the example of FIG. 4) simplifies design of a MEMS device while providing some via compression in a target direction (e.g., the Y direction in FIG. 4). In some examples, elongated via dimensions are selected to provide balance between a target spacing and structural/electrical integrity. Having a compressed dimension in a first direction (e.g., the Y direction) improves spacing along the first direction, while having a larger dimension in a second direction (e.g., the X direction) increases via sidewall thickness in the second direction. With the mirror via 418 being an elongated via (due to being compressed in the Y direction) as in FIG. 4, spacing between hinge layer components and/or electrode layer components is improved in the Y direction, while providing structural and electrical integrity of the mirror via 418. With increased spacing between hinge layer components and/or electrode layer components in the Y direction, a MEMS device with the MEMS device components of FIG. 4 may be smaller or more miniaturized compared to a MEMS device with only symmetric vias.

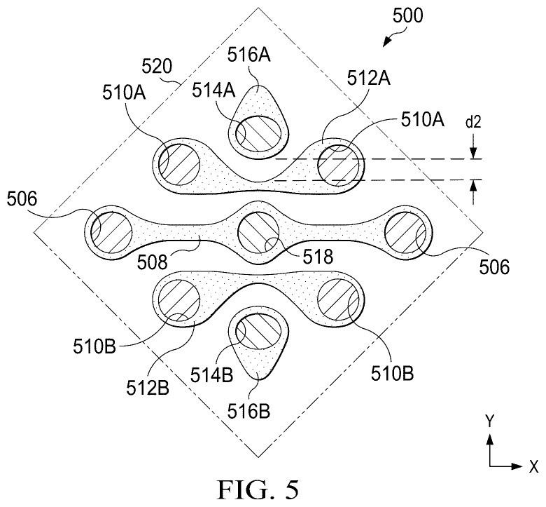

FIG. 5 is a see-through top view 500 of MEMS device components in accordance with various examples. In the see-through top view 500 of FIG. 5, the relative position, size, and spacing of torsion hinge vias 506, a torsion hinge 508, first electrode vias 510A, second electrode vias 510B, a first raised electrode 512A, a second raised electrode 512B, a first spring tip via 514A, a second spring tip via 514B, a first spring tip 516A, a second spring tip 516B, a mirror via 518, and a mirror 520 are shown. The torsion hinge vias 506 are examples of the hinge vias 206 in FIGS. 2A to 2E. The torsion hinge 508 is an example of the torsion hinge 208 in FIGS. 2A to 2E. The first electrode vias 510A are examples of the first electrode vias 210A in FIGS. 2A-2E. The second electrode vias 510B are examples of the second electrode vias 210B in FIGS. 2A-2E. The first raised electrode 512A is an example of the first raised electrode 212A in FIGS. 2A to 2E. The second raised electrode 512B is an example of the second raised electrode 212B in FIGS. 2A to 2E. The first spring tip via 514A is an example of the first spring tip via 214A in FIGS. 2A to 2E. The second spring tip via 514B is an example of the second spring tip via 214B in FIGS. 2A to 2E. The first spring tip 516A is an example of the first spring tip 216A in FIGS. 2A to 2E. The second spring tip 516B is an example of the second spring tip 216B in FIGS. 2A to 2E. The mirror via 518 is an example of the mirror via 218 in FIGS. 2A to 2E. The mirror 520 is an example of the mirror 220 in FIGS. 2A to 2E.

In the example of FIG. 5, the first spring tip via 514A is elongated (compressed in the Y direction), which increases the spacing d2 between the first spring tip via 514A and the first raised electrode 512A. The second spring tip via 514B is also elongated (compressed in the Y direction), which provides the spacing d2 between the second spring tip via 514B and the second raised electrode 512B. In the example of FIG. 5, each of the first and second spring tip vias 514A and 514B has an elongation orientation parallel to the first and second raised electrodes 412A and 412B so that the spacing d2 is increased relative to a MEMS device design with only symmetric vias. The torsion hinge vias 506, the first electrode vias 510A, the second electrode vias 510B, the first spring tip via 514A, and the second spring tip via 514B are symmetric vias in FIG. 5, which may reduce design time and related costs. The spacing d2 between spring tips and respective raised electrodes due to use of elongated vias for the first spring tip via 514A and the second spring tip via 514B may facilitate layout, spacing, and/or miniaturization of a particular MEMS device or related product. In some examples, elongated vias dimensions are selected to provide balance between a target spacing and structural/electrical integrity. Having a smaller dimension in a first direction (e.g., the Y direction in FIG. 5) improves spacing along the Y direction, while having a larger dimension in a second direction (e.g., the X direction in FIG. 5) increases via sidewall thickness in the second direction. With the first spring tip via 514A and the second spring tip via 514B being elongated as in FIG. 5, spacing between hinge layer components and/or electrode layer components is increased in the Y direction, while providing structural and electrical integrity of the first spring tip via 514A and the second spring tip via 514B. Compared to the MEMS device components of FIG. 4 (where only the mirror via 418 is an elongated via compressed in the Y direction), the MEMS device components of FIG. 5 (where only the first and second spring tip vias 514A and 514B are elongated vias compressed in the Y direction) increase the spacing between hinge layer components and/or electrode layer components in the Y direction. With increased spacing between hinge layer components and/or electrode layer components in the Y direction, a MEMS device with the MEMS device components of FIG. 5 may be smaller or more miniaturized compared to a MEMS device with the MEMS device components of FIG. 4.

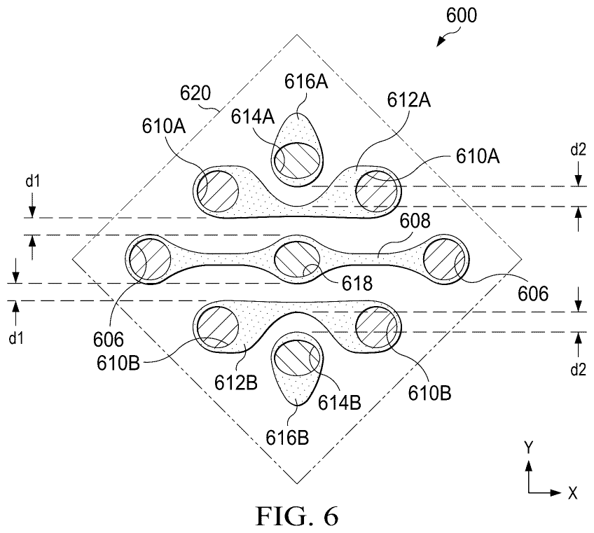

FIG. 6 is a see-through top view 600 of MEMS device components in accordance with various examples. In the see-through top view 600 of FIG. 6, the relative position, size, and spacing of torsion hinge vias 606, a torsion hinge 608, first electrode vias 610A, second electrode vias 610B, a first raised electrode 612A, a second raised electrode 612B, a first spring tip via 614A, a second spring tip via 614B, a first spring tip 616A, a second spring tip 616B, a mirror via 618, and a mirror 620 are shown. The torsion hinge vias 606 are examples of the hinge vias 206 in FIGS. 2A to 2E. The torsion hinge 608 is an example of the torsion hinge 208 in FIGS. 2A to 2E. The first electrode vias 610A are examples of the first electrode vias 210A in FIGS. 2A-2E. The second electrode vias 610B are examples of the second electrode vias 210B in FIGS. 2A-2E. The first raised electrode 612A is an example of the first raised electrode 212A in FIGS. 2A to 2E. The second raised electrode 612B is an example of the second raised electrode 212B in FIGS. 2A to 2E. The first spring tip via 614A is an example of the first spring tip via 214A in FIGS. 2A to 2E. The second spring tip via 614B is an example of the second spring tip via 214B in FIGS. 2A to 2E. The first spring tip 616A is an example of the first spring tip 216A in FIGS. 2A to 2E. The second spring tip 616B is an example of the second spring tip 216B in FIGS. 2A to 2E. The mirror via 618 is an example of the mirror via 218 in FIGS. 2A to 2E. The mirror 620 is an example of the mirror 220 in FIGS. 2A to 2E.

In the example of FIG. 6, the mirror via 618 is elongated, which increases the spacing d1 between the mirror via 618 and the first and second raised electrodes 612A and 612B. Also, the first and second spring tip vias 614A and 614B are elongated, which increases the spacing d2 between the first spring tip via 614A and the first raised electrode 612A, and the spacing d2 between the second spring tip via 614B and the second raised electrode 612B. In the example of FIG. 5, each of the mirror via 618, the first spring tip via 514A, and the second spring tip via 514B has an elongation orientation parallel to the first and second raised electrodes 612A and 612B so that the spacings d1 and d2 are increased relative to a MEMS device design with only symmetric vias. The combination of elongated vias in FIG. 6 may facilitate layout, spacing, and/or miniaturization of a particular MEMS device or related product. In some examples, elongated vias dimensions are selected to provide balance between a target spacing and structural/electrical integrity. Having a smaller dimension in a first direction (e.g., the Y direction in FIG. 6) improves spacing along the first direction, while having a larger dimension in a second direction (e.g., the X direction in FIG. 6) increases via sidewall thickness in the second direction. With the mirror via 618, the first spring tip via 614A, and the second spring tip via 614B being elongated as in FIG. 6, spacing between hinge layer components and/or electrode layer components is improved in the Y direction, while providing structural and electrical integrity of the mirror via 618, the first spring tip via 614A, and the second spring tip via 614B. Compared to the MEMS device components of FIG. 4 (where only the mirror via 418 is an elongated via compressed in the Y direction) and the MEMS device components of FIG. 5 (where only the first and second spring tip vias 514A and 514B are elongated vias compressed in the Y direction), the MEMS device components of FIG. 6 (where the mirror via 618, the first spring tip via 614A, and the second spring tip via 614B are elongated vias compressed in the Y direction) increase the spacing between hinge layer components and/or electrode layer components in the Y direction. With increased spacing between hinge layer components and/or electrode layer components in the Y direction, a MEMS device with the MEMS device components of FIG. 6 may be smaller or more miniaturized compared to MEMS devices with the MEMS device components of FIG. 4 or FIG. 5.

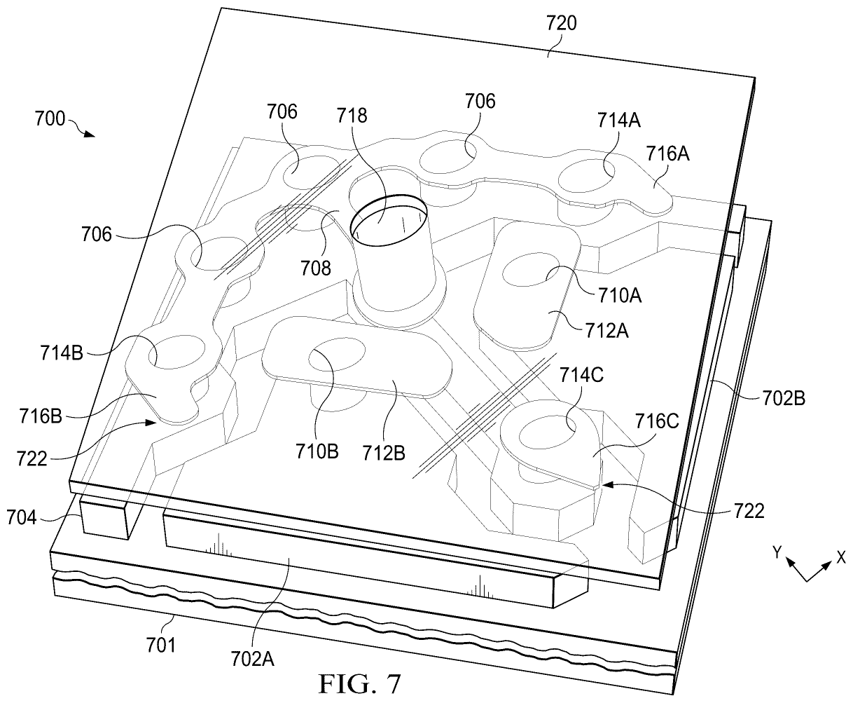

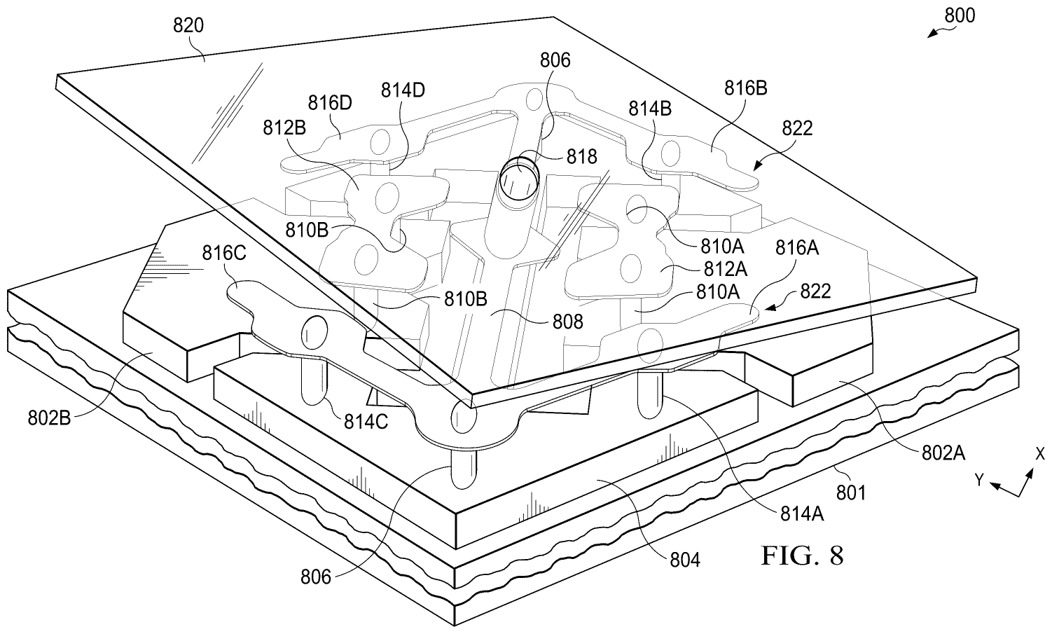

In the examples of FIGS. 2A to 2E, and 4 to 6, the MEMS device may be part of a single spring tip pixel. In other examples, a MEMS device with elongated vias may be part of a TRP element as in FIG. 7. In other examples, a MEMS device with elongated vias may be part of a dual spring tip pixel as in FIG. 8. Regardless of whether a MEMS device is part of a single spring tip pixel, a TRP element, a dual spring tip pixel, or other device, use of one or more elongated vias (compressed in a target direction) may be used to achieve a target size for the MEMS device or related pixel. In some examples, elongated vias may be used for MEMS devices or a related pixel having a target size of 6 um pixels, 5.5 um pixels, 5.0 um pixels, 4.5 um pixels, 4.0 um pixels, 3.6 um pixels, 2.7 um pixels, or smaller pixels.

In some examples, a MEMS device includes: a hinge layer (e.g., the hinge layer 108 in FIGS. 1A and 1B, or the hinge layer 224 in FIGS. 2A to 2E, or related components in FIGS. 3, 5-8, and 10-12); a second layer (e.g., the moving element(s) layer 110 in FIGS. 1A and 1B, the mirror layer 226 in FIGS. 2A to 2E, the electrode layer 106 in FIGS. 1A and 1B, or the electrode layer 222 in FIGS. 2A to 2E); and an elongated via (e.g., the elongated via(s) 112 and 114 in FIGS. 1A and 1B, the first electrode vias 210A, the second electrode vias 210B, the first spring tip via 214A, or the second spring tip via 214B in FIGS. 2A to 2E, or related elongated vias FIGS. 6, 10, and 12) coupled between the hinge layer and the second layer. In some examples, the second layer is a mirror layer. In some examples, the second layer is an electrode layer including an electrode, and the elongated via couples the electrode and the hinge layer. In some examples, the electrode is a bias electrode. In some examples, the hinge layer includes a spring tip, and the elongated via couples the bias via and the spring tip. In some examples, the hinge layer includes a hinge, and the elongated via couples the bias via and the hinge. In some examples, the hinge layer includes a raised electrode, and the elongated via couples the raised electrode and the electrode.

In some examples, the elongated via is a first elongated via, the MEMS device comprises a second elongated via, the second layer includes an electrode, the first elongated via is a mirror via, the second elongated via is a spring tip via. In such examples, the mirror via may be spaced from a first side of the electrode by 0.125 um up to 0.15 um. Also, the spring tip via may be spaced from a second side of the electrode by 0.15 um up to 0.175 um or more. In different examples, such spacing may vary depending on pixel size and fabrication tolerances. In some examples, the elongated via has a hollow elongated cylinder shape. In some examples, the MEMS device is part of TRP element with is 5 um size or less. In some examples, the MEMS device is part of a dual spring tip pixel with a 6 um size, a 5.5 um size, a 5.0 um size, a 4.5 um size, a 4.0 um size, a 3.6 um size, a 2.7 um size, or smaller. In some examples, a MEMS device includes: a mirror layer (e.g., the moving element(s) layer 110 in FIGS. 1A and 1B, or mirror layer 226 in FIGS. 2A to 2E); an electrode layer (e.g., the electrode layer 106 in FIGS. 1A and 1B, or the electrode layer 222 in FIGS. 2A to 2E); a hinge layer (e.g., the hinge layer 108 in FIGS. 1A and 1B, or the hinge layer 224 in FIGS. 2A to 2E); a mirror via (e.g., the mirror via 218 in FIG. 2A to 2E, the mirror via 618 in FIG. 6, the mirror via 518 in FIG. 5, or the mirror via 618 in FIG. 6) coupling the mirror layer and the hinge layer; and an elongated via (e.g., the elongated via(s) 112 in FIGS. 1A and 1B, or the first electrode vias 210A, the second electrode vias 210B, the first spring tip via 214A, or the second spring tip via 214B in FIGS. 2A to 2E) coupling the hinge layer and the electrode layer.

In some examples, the electrode layer includes an electrode (e.g., the bias electrode 204 in FIGS. 2A to 2E), the hinge layer includes a torsion hinge (e.g., the torsion hinge 208 in FIGS. 2A to 2E), and the elongated via couples the torsion hinge and the electrode. In some examples, the electrode layer includes an electrode (e.g., the bias electrode 204 in FIGS. 2A to 2E), the hinge layer includes a spring tip (e.g., the first spring tip 216A or the second spring tip 216B in FIGS. 2A to 2E), and the elongated via couples the spring tip and the electrode. In some examples, the electrode layer includes an electrode (e.g., the first address electrode 202A or the second address electrode 202B in FIGS. 2A to 2E), the hinge layer includes a raised electrode (e.g., the first raised electrode 212A or the second raised electrode 212B in FIGS. 2A to 2E), and the elongated via couples the raised electrode and the electrode. In some examples, the mirror via is an elongated mirror via.

In some examples, a MEMS device (e.g., the MEMS device 102 in FIGS. 1A and 1B, or MEMS device components in FIGS. 2A to 2E, 6, 10, or 12) includes: a mirror layer (e.g., the moving element(s) layer 110 in FIGS. 1A and 1B, or mirror layer 226 in FIGS. 2A to 2E); an electrode layer (e.g., the electrode layer 106 in FIGS. 1A and 1B, or the electrode layer 222 in FIGS. 2A to 2E) including a first electrode (e.g., the bias electrode 204 in FIGS. 2A to 2E) and a second electrode (e.g., the first address electrode 202A or the second address electrode 202B in FIGS. 2A to 2E) spaced from the first electrode; a hinge layer (e.g., the hinge layer 108 in FIGS. 1A and 1B, or the hinge layer 224 in FIGS. 2A to 2E) including a hinge (e.g., the torsion hinge 208 in FIGS. 2A to 2E); an elongated via (e.g., the mirror via 218 in FIGS. 2A to 2E) coupling the hinge and the mirror layer; and a hinge via (e.g., the hinge via 206 in FIGS. 2A to 2E) coupling the hinge and the first electrode. In some examples, the hinge via is elongated.

In some examples, the hinge layer includes a spring tip, and the MEMS device further comprises an elongated spring tip via coupling the spring tip and the first electrode, wherein the first electrode is a bias electrode. In some examples, the hinge layer includes a raised electrode, and the MEMS device further comprising an elongated electrode via coupling the raised electrode and the second electrode.

FIGS. 7 to 10 are perspective views of other MEMS devices 700, 800, 900, and 1000 and in accordance with various examples. In FIG. 7, the MEMS device 700 is an example of a TRP pixel (sometimes referred to as a “cantilever” pixel). In the example of FIG. 7, the MEMS device 700 includes a base 701, electrode layer components, hinge layer components, mirror layer components, and elongated via(s). In the example of FIG. 7, the base 701 is split to represent its thickness may vary. The base 701 may include memory cells to control different states of the MEMS device 700 responsive to received data. The electrode layer components include a first address electrode 702A, a second address electrode 702B, and a bias electrode 704. The hinge layer components include a cantilever hinge 708, spring tips 716A to 716C, a first raised electrode 712A, a first electrode via 710A, a second raised electrode 712B, and a second electrode via 710B. The mirror layer components include a mirror 720. In the example of FIG. 7, various elongated vias are represented including spring tip vias 714A to 714C, the first electrode via 710A, the second electrode via 710B, hinge vias 706, and a mirror via 718. In the example of FIG. 7, each of the elongated vias is elongated in the X direction and/or is compressed in the Y direction compared to a symmetric via. With the elongated vias of FIG. 7, spacing between hinge layer components and/or electrode layer components is increased in the Y direction, which may facilitate miniaturization of the MEMS device 700. In different examples, some of the spring tip vias 714A to 714C, the first electrode via 710A, the second electrode via 710B, the hinge vias 706, and the mirror via 718 may be symmetric vias while other vias are elongated vias (e.g., as in FIGS. 4 to 6). In different examples, the number of elongated vias and/or the aspect ratio of elongation used for elongated vias may vary to support different levels of miniaturization subject to fabrication tolerances.

As shown, the position of the mirror 720 is tilted. In an example SLM, the position of the mirror 720 switches between different tilted positions responsive to: received data; control voltages applied to the first address electrode 702A, the second address electrode 702B, and the bias electrode 704 responsive to received data; and movement of the cantilever hinge 708 and mirror 720 responsive to application of the control voltages.

In the example of FIG. 7, the mirror 720 is in a first position, in which the mirror 720 contacts the spring tips 716B and 716C at contact points 722 responsive to control voltages applied to the first address electrode 702A, the second address electrode 702B, and the bias electrode 704. To change the position of the mirror 720 to another position (e.g., the mirror 720 may contact the spring tips 716A and 716B), updated control voltages are applied to the first address electrode 702A, the second address electrode 702B, and/or the bias electrode 704.

In different examples, the number of total vias and the number of elongated vias between hinge layer components and electrode layer components may vary. Similarly, in different examples, the number of total vias and the number of elongated vias between hinge layer components and mirror layer components may vary. The dimensions of each elongated via may vary and may be selected to facilitate layout, spacing, and/or miniaturization of a particular MEMS device or related product. Without limitation, the MEMS device 700 may be used to form a TRP pixel of a SLM of a display system. Example pixel sizes that may benefit from the MEMS device 700 and related elongated vias include 6 um pixels, 5.5 um pixels, 5.0 um pixels, 4.5 um pixels, 4.0 um pixels, 3.6 um pixels, 2.7 um pixels, or smaller pixels.

In FIG. 8, the MEMS device 800 is an example of a dual spring tip pixel. In the example of FIG. 8, the MEMS device 800 includes a base 801, electrode layer components, hinge layer components, mirror layer components, and elongated via(s). In the example of FIG. 8, the base 801 is split to represent its thickness may vary. The base 801 may include memory cells to control different states of the MEMS device 800 responsive to received data. The electrode layer components include a first address electrode 802A, a second address electrode 802B, and a bias electrode 804. The hinge layer components include a torsion hinge 808, spring tips 816A to 816D, a first raised electrode 812A, and a second raised electrode 812B. The mirror layer components include a mirror 820. In the example of FIG. 8, various elongated vias are represented including spring tip vias 814A, 814B, 814C, and 814D, first electrode vias 810A, second electrode vias 810B, hinge vias 806, and a mirror via 818. In the example of FIG. 8, each of the elongated vias is elongated in the X direction and/or is compressed in the Y direction compared to a symmetric via. With the elongated vias of FIG. 8, spacing between hinge layer components and/or electrode layer components is increased in the Y direction, which may facilitate miniaturization of the MEMS device 800. In different examples, some of the spring tip vias 814A to 814D, first electrode vias 810A, second electrode vias 810B, hinge vias 806, and the mirror via 818 may be symmetric vias while others are elongated vias (e.g., as in FIGS. 4 to 6). In different examples, the number of elongated vias and/or the aspect ratio of elongation used for elongated vias may vary to support different levels of miniaturization subject to fabrication tolerances.

As shown, the position of the mirror 820 is tilted. In an example SLM, the position of the mirror 820 switches between different tilted positions responsive to: received data; control voltages applied to the first address electrode 802A, the second address electrode 802B, and the bias electrode 804 responsive to received data; and movement of the torsion hinge 808 and mirror 820 responsive to application of the control voltages.

In the example of FIG. 8, the mirror 820 is in a first position, in which the mirror 820 contacts the spring tips 816A and 816B at contact points 822 responsive to control voltages applied to the first address electrode 802A, the second address electrode 802B, and the bias electrode 804. To change the position of the mirror 820 to another position (e.g., the mirror 820 may contact the spring tips 816C and 816D), updated control voltages are applied to the first address electrode 802A, the second address electrode 802B, and/or the bias electrode 804.

In different examples, the number of total vias and the number of elongated vias between hinge layer components and electrode layer components may vary. Similarly, in different examples, the number of total vias and the number of elongated vias between hinge layer components and mirror layer components may vary. The dimensions of each elongated via may vary and may be selected to facilitate layout, spacing, and/or miniaturization of a particular MEMS device or related product. Without limitation, the MEMS device 800 may be used to form a dual spring tip pixel of a SLM of a display system. Example pixel sizes that may benefit from the MEMS device 800 and related elongated vias include 6 um pixels, 5.5 um pixels, 5.0 um pixels, 4.5 um pixels, 4.0 um pixels, 3.6 um pixels, 2.7 um pixels, or smaller pixels.

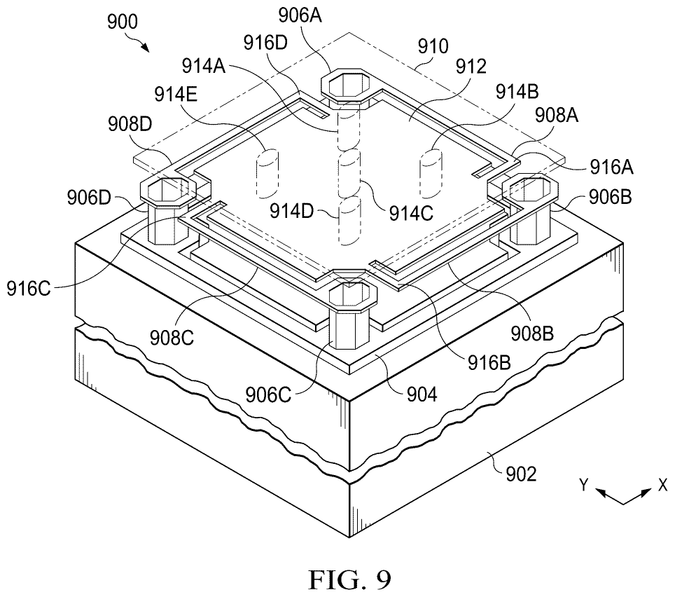

In FIG. 9, the MEMS device 900 is an example of a phase light modulator (PLM) or related pixel. The MEMS device 900 includes a base 902, bottom electrode 904, support posts 906A, 906B, 906C, and 906D (sometimes referred to collectively as support posts 906 herein), hinges 908A, 908B, 908C, and 908D (sometimes referred to collectively as hinges 908 herein), mirror plate 910, top plate 912, and mirror via posts 914A, 914B, 914C, 914D, and 914E (sometimes referred to collectively as mirror via posts 914 herein). Support posts 906, hinges 908, mirror plate 910, top plate 912, and mirror via posts 914 may be aluminum alloys in one example. In the example of FIG. 9, the base 902 is split to represent its thickness may vary. In some examples, the base 902 includes a CMOS memory array, such as an SRAM memory array. Bottom electrode 904 is also referred to as an electrode structure. In some examples, the bottom electrode 904 includes four segments (e.g., four electrodes) and a bias electrode. The four electrodes may be individually addressed to provide sixteen discrete positions for mirror plate 910. Support posts 906 couple the bias electrode portion of bottom electrode 904 to hinges 908. Each of the hinges 908 is coupled to an outside edge of a support post 906, away from the center of top plate 912. If hinges 908 were coupled to the center of a support post 906, top plate 912 would be smaller. In the example of FIG. 9, top plate 912 is larger. A larger top plate allows for more electrostatic force to be created between bottom electrode 904 and top plate 912. The hinges 908 are also coupled to top plate 912. In addition, each hinge 908 has a 90 degree turn 916A, 916B, 916C, and 916D, (sometimes referred to collectively as turns 916 herein) where the hinge couples to top plate 912. The turns 916 provide flexibility for a hinge 908, so the hinge 908 may flex if a voltage difference exists between top plate 912 and bottom electrode 904, which allows top plate 912 to move up and down relative to bottom electrode 904. Mirror plate 910 is coupled to top plate 912 by way of mirror via posts 914 (shown as dashed lines in FIG. 1A).

In operation, a bias voltage is applied to support posts 906, hinges 908, top plate 912, and mirror plate 910, which are coupled to one another and therefore are each at the same bias voltage. The bias voltage may be 0 V in one example, or could be another voltage in another example. Voltages greater than 0 V are applied to some combination of the four segments of bottom electrode 904. The voltage difference between the bottom electrode 904 and the top plate 912 creates an electrostatic force that pulls the top plate 912 down toward bottom electrode 904. Mirror plate 910 moves down with top plate 912 as well. The movement up and down of top plate 912 and mirror plate 910 (with respect to bottom electrode 904) modulates the phase of the light that is reflected by mirror plate 910. Voltages are applied to different combinations of the segments of bottom electrode 904 to move mirror plate 910 and top plate 912 to different vertical positions. Moving the mirror plate 910 up and down at a high frequency modulates the phase of the reflected light, and images are produced using an array of mirror plates 910.

In some examples, the MEMS device 900 has a 4-bit electrode design for bottom electrode 904, which provides up to sixteen discrete vertical positions for mirror plate 910. With the MEMS device 900, each hinge 908 connects tangentially to an edge, instead of a center, of a support post 906. By connecting to an edge of a support post 906, top plate 912 is larger, and more usable area beneath top plate 912 is available for bottom electrode 904. A larger bottom electrode 904 allows for more electrostatic force to be created between bottom electrode 904 and top plate 912, which is useful for increasing the amount of vertical movement of top plate 912 and mirror plate 910.

In FIG. 9, the support posts 906 and the mirror via posts 914 are examples of elongated vias, where each of the support posts 906 and the mirror via posts 914 are elongated in the X direction and compressed in the Y direction. With the elongated vias of FIG. 9, spacing between hinge layer components and/or electrode layer components is increased in the Y direction, which may facilitate miniaturization of the MEMS device 900. In different examples, some of the support posts 906 and the mirror via posts 914 may be symmetric vias while others are elongated vias. In different examples, the number of elongated vias and/or the aspect ratio of elongation used for elongated vias may vary to support different levels of miniaturization subject to fabrication tolerances.

In different examples of the MEMS device 900, the number of total vias and the number of elongated vias between hinge layer components and electrode layer components may vary. Similarly, in different examples, the number of total vias and the number of elongated vias between hinge layer components and mirror layer components of the MEMS device 900 may vary. The dimensions of each elongated via may vary and may be selected to facilitate layout, spacing, and/or miniaturization of a particular MEMS device or related product. Without limitation, the MEMS device 900 may be used to form a pixel of a PLM of a display system. Example pixel sizes that may benefit from the MEMS device 900 and related elongated vias include 6 um pixels, 5.5 um pixels, 5.0 um pixels, 4.5 um pixels, 4.0 um pixels, 3.6 um pixels, 2.7 um pixels, or smaller pixels.

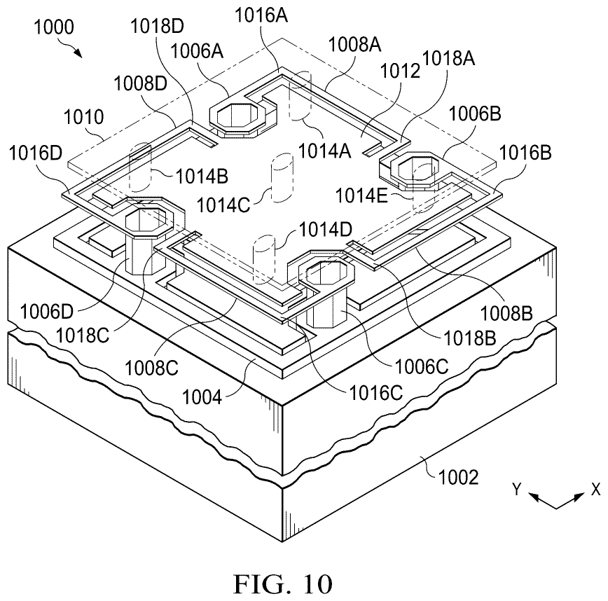

In FIG. 10, the MEMS device 1000 is an example of another PLM or related pixel. In some examples, the MEMS device 1000 has a 4-bit electrode design. The MEMS device 1000 includes a base 1002, bottom electrode 1004, support posts 1006A, 1006B, 1006C, and 1006D (sometimes referred to collectively as support posts 1006 herein), hinges 1008A, 1008B, 1008C, and 1008D (sometimes referred to collectively as hinges 1008 herein), mirror plate 1010, top plate 1012, and mirror via posts 1014A, 1014B, 1014C, 1014D, and 1014E (sometimes referred to collectively as mirror via posts 1014 herein). Support posts 1006, hinges 1008, mirror plate 1010, top plate 1012, and mirror via posts 1014 may be aluminum alloys in one example. In the example of FIG. 10, the base 1002 is split to represent its thickness may vary. In some examples, the base 1002 includes a CMOS SRAM memory array. Bottom electrode 1004 is also referred to as an electrode structure. In some examples, the bottom electrode 1004 includes four segments that are individually addressed to provide up to sixteen discrete positions for mirror plate 1010. Bottom electrode 1004 may also include a bias electrode. Support posts 1006 couple the bias electrode portion of bottom electrode 1004 to hinges 1008. Each of hinges 1008 is coupled to an outside edge of a support post 1006, away from the center of top plate 1012 (instead of being coupled to the center of a support post 1006). The hinges 1008 are also coupled to top plate 1012. In addition, each of the hinges 1008 has two 90 degree turns: one turn at a corner of the MEMS device 1000 (turns 1016A, 1016B, 1016C, and 1016D, collectively turns 1016) and one turn where the hinge couples to top plate 1012 (turns 1018A, 1018B, 1018C, and 1018D, collectively turns 1018). The turns 1016 and 1018 provide flexibility for a hinge 1008, so the hinge 1008 may flex if a voltage difference exists between top plate 1012 and bottom electrode 1004, which allows top plate 1012 to move up and down relative to bottom electrode 1004. Two turns in each hinge 1008 may provide more relief of hinge stresses than one turn in each hinge 1008. Mirror plate 1010 is coupled to top plate 1012 by way of mirror via posts 1014 (shown as dashed lines in FIG. 10).

The MEMS device 1000 of FIG. 10 operates similarly to the MEMS device 900 of FIG. 9. In short, the voltage differential between the bottom electrode 1004 and the top plate 1012 creates an electrostatic force that pulls the top plate 1012 down toward bottom electrode 1004. Mirror plate 1010 moves down with top plate 1012 as well. The movement up and down of mirror plate 1010 modulates the phase of the light that is reflected by mirror plate 1010 to produce images.

In some examples, the bottom electrode 1004 of the MEMS device 1000 has a 4-bit electrode design to provide up to sixteen discrete vertical positions for mirror plate 1010. With the MEMS device 1000, each hinge 1008 couples to top plate 1012 on an adjacent side from a support post 1006 that each respective hinge couples to. For example, hinge 1008A couples to support post 1006A. Hinge 1008A couples to top plate 1012 on a side of top plate 1012 that is adjacent to the side of top plate 1012 where support post 1006A is located. The hinge design shown for the MEMS device 1000 may provide increased hinge compliance and additional relief of hinge stresses for better thermal stability compared to the MEMS device 900. Also, the MEMS device 1000 allows alternate locations for support posts 1006 compared to the MEMS device 900.

In FIG. 10, the support posts 1006 and the mirror via posts 1014 are examples of elongated vias, where each of the support posts 1006 and the mirror via posts 1014 are elongated in the X direction and compressed in the Y direction. With the elongated vias of FIG. 10, spacing between hinge layer components and/or electrode layer components is increased in the Y direction, which may facilitate miniaturization of the MEMS device 1000. In different examples, some of the support posts 1006 and the mirror via posts 1014 may be symmetric vias while others are elongated vias. In different examples, the number of elongated vias and/or the aspect ratio of elongation used for elongated vias may vary to support different levels of miniaturization subject to fabrication tolerances.

In different examples, the number of total vias and the number of elongated vias between hinge layer components and electrode layer components of the MEMS device 1000 may vary. Similarly, in different examples, the number of total vias and the number of elongated vias between hinge layer components and mirror layer components of the MEMS device 1000 may vary. The dimensions of each elongated via may vary and may be selected to facilitate layout, spacing, and/or miniaturization of a particular MEMS device or related product. Without limitation, the MEMS device 1000 may be used to form a pixel of a PLM of a display system. Example pixel sizes that may benefit from the MEMS device 1000 and related elongated vias include 6 um pixels, 5.5 um pixels, 5.0 um pixels, 4.5 um pixels, 4.0 um pixels, 3.6 um pixels, 2.7 um pixels, or smaller pixels.

In the examples of FIGS. 2A to 2E and 4 to 10, elongated vias are elongated in the X direction and compressed in the Y direction. Depending on the layout of electrode layer components and/or hinge layer components, elongated vias may elongated in the Y direction and compressed in the X direction. As another option, elongated vias may be elongated diagonally to the X and Y directions or another angle (and compressed orthogonally to the direction of elongation) as needed to increase spacing between electrode layer components and/or hinge layer components. In different examples, the amount of elongation, the amount of compression and the related aspect ratio of elongated vias may vary to achieve a target miniaturization for a MEMS device subject to fabrication tolerances.

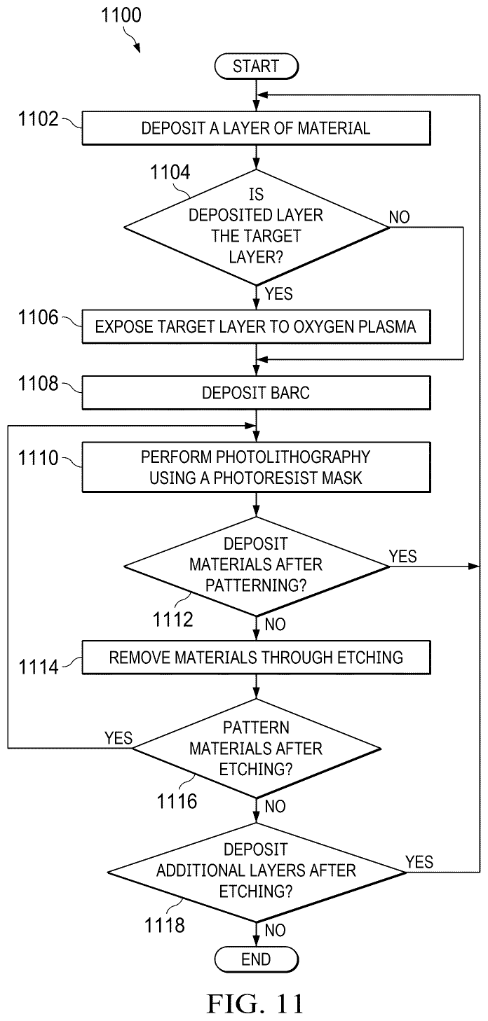

FIG. 11 is a flowchart representative of a method 1100 to fabricate a MEMS device as described in accordance with the teachings of this disclosure. The example method 1100 begins by depositing a layer of material onto the top of a surface at block 1102. In some examples, the surface is a wafer made from a material used as a substrate (e.g., silicon). The layer deposited at block 1102 may be made from any suitable material (e.g., metals, organic materials, etc.). Block 1102 may be performed using any IC deposition technique, including but not limited to chemical vapor deposition, atomic layer deposition, physical vapor deposition, molecular-beam epitaxy, etc.

The example method 1100 includes a determination whether the deposited layer is the target layer at block 1104. The target layer is a layer of material that will be exposed to oxygen plasma to control shape and stress. The target layer is also a structural layer that will be used to form one or more components of a MEMS device. Example structural layers may be used to form electrode layer components, hinge layer components, a mirror or other moving elements, and vias including elongated vias as described herein.

If the deposited layer of block 1102 is not the target layer (block 1104: No), the method 1100 proceeds to block 1108. Alternatively, if the deposited layer of block 1102 is the target layer (block 1104: Yes), the method 1100 includes usage of a plasma etcher to expose the target layer to oxygen plasma at block 1106. In some examples, a plasma etcher performs block 1106 for a specific duration of time and at a specific power setting to achieve a particular shape and stress gradient within the target layer. The target layer is continuously distributed across the entire wafer (i.e., in a blanket state) when the plasma etcher exposes the layer to oxygen plasma at block 1106.

After the example oxidization procedure of block 1106, or if the deposited layer of block 1102 is not the target layer (block 1104: No), a bottom anti-reflective coating (BARC) pattern may optionally be deposited at block 1108. If implemented, block 1108 occurs after the target layer is exposed to oxygen plasma but before patterning. Depositing a BARC layer may avoid reflections from occurring under the photoresist and improve the photoresist's performance at smaller semiconductor nodes.

The method 1100 includes performing photolithography using a photoresist mask to expose specific portions of the wafer at block 1110. The patterning of block 1110 may be performed using any IC deposition technique, including but not limited to optical lithography, electron beam lithography, soft lithography, x-ray lithography, etc.

The example method 1100 includes determining whether to deposit additional materials before patterning the deposited layer at block 1112. If deposition is required after patterning (block 1112: Yes), control returns back to block 1102. Deposition after patterning may result in the addition of material at non-uniform depths across the wafer.

If deposition is not required after patterning (block 1112: No), the method 1100 includes usage of a plasma etcher tool to etch the material stack to remove portions of material based on the photoresist at block 1114. Block 1114 may be performed using any suitable etching technique, including but not limited to wet etching, isotropic radical etching, reactive ion etching, physical sputtering and ion milling, etc. The final iteration of block 1114 may be referred to as a release stage, during which sacrificial layers are removed and the MEMS device becomes a stand-alone structure.

The example method 1100 includes a determination whether to pattern materials after etching at block 1116. If patterning is required after patterning (block 1116: Yes), the method 1100 returns to block 1110. Alternatively, if patterning is not required after etching (block 1116: No), the method 1100 includes a determination whether to deposit additional layers after patterning at block 1118. If additional layers are to be deposited (block 1118: Yes), the method 1100 returns to block 1102. If no additional layers remain to be deposited (block 1118: No), the MEMS fabrication is complete and the example method 1100 ends.

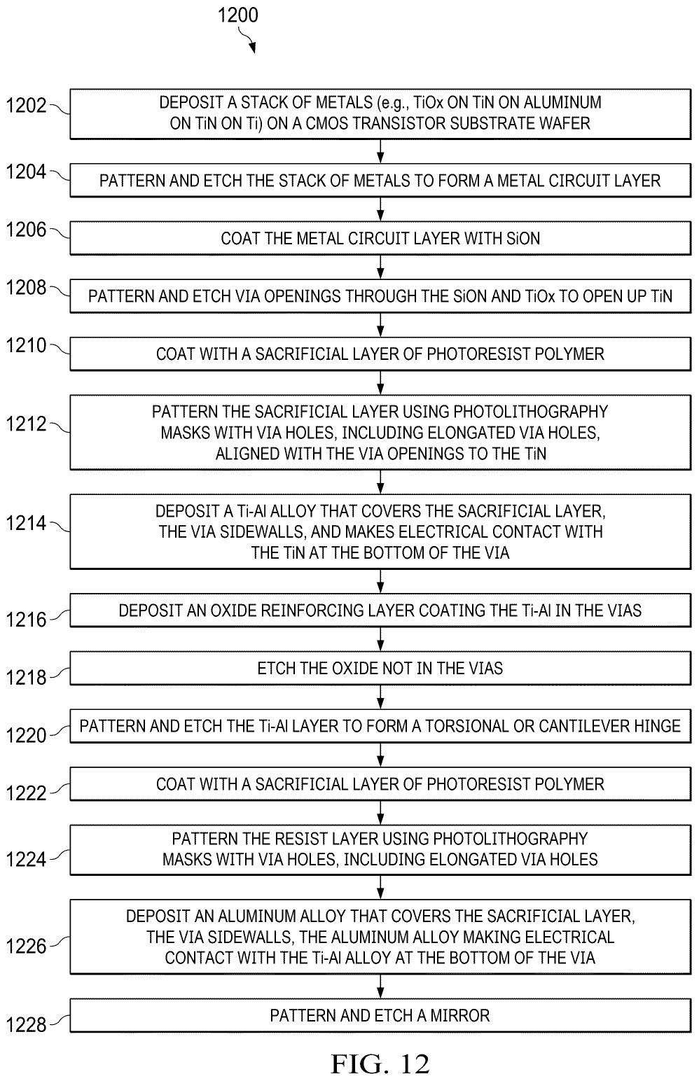

FIG. 12 is a flowchart showing another MEMS device fabrication method 1200 in accordance with various examples. To complete the MEMS device fabrication method 1200, some or all of the MEMS device fabrication method 1100 may be used. FIGS. 13A to 13M are cross-sectional views of MEMS device fabrication steps in accordance with various examples and which represent at least some of the steps or results of the MEMS device fabrication method 1200. In FIGS. 13A to 13M, the layers are not to scale.

As shown, the MEMS device fabrication method 1200 includes depositing a stack of metals (e.g., TiOx on TIN on aluminum on TIN on Ti) on a CMOS transistor substrate wafer at block 1202. The cross-sectional view 1300A of FIG. 13A shows an example stack of metals 1302 resulting from the operations of block 1202. At block 1204, the stack of metals is patterned and etched to form a metal circuit layer. At block 1206, the metal circuit layer is coated with a sacrificial spacer via layer (e.g., SiON). At block 1208, via openings are patterned and etched through the sacrificial spacer via layer and TiOx to open up the TiN layer of the stack metals. At block 1210, the result of block 1208 is coated with a sacrificial layer (e.g., of photoresist polymer). At block 1212, the sacrificial layer is patterned using photolithographic masks with via holes, including elongated via holes, aligned with the via openings to the TiN layer. The cross-sectional views 1300B and 1300C of FIGS. 13B and 13C show a patterned and etched stack of metals 1302 and a first sacrificial spacer via layer 1304 resulting from blocks 1204, 1206, 1208, 1210, and 1212. In the cross-sectional views 1300B and 1300C of FIGS. 13B and 13C, the via patterned and etched in the first sacrificial spacer via layer 1304 has a length L3 and a width W3, where the width W3 is greater than length L3 (i.e., the via is an elongated via). In some examples, the length L3 is comparable to the length L2 in FIG. 3, and the width W3 is comparable to the width W2 in FIG. 3. Comparing the views of FIGS. 13B and 13C, the cross-sectional view 1300B is orthogonal to the cross-sectional view 1300C.

At block 1214, a Ti—Al alloy that covers the sacrificial layer and the via sidewall formed during block 1212 is deposited. The Ti—Al layer makes electrical contact with the TiN layer at the bottom of the via formed during block 1212. The cross-sectional views 1300D and 1300E of FIGS. 13D and 13E show hinge layer metal 1306 with thickness 1305 resulting from block 1214. As shown, in FIGS. 13D and 13E, the hinge layer metal 1306 cover the via formed in the first sacrificial spacer via layer 1304. In some examples, the hinge layer metal 1306 may have an elongated via shape (e.g., a width based on width W3 and a length based on length L3) as shown in FIGS. 13D and 13E. Comparing the views of FIGS. 13D and 13E, the cross-sectional view 1300D is orthogonal to the cross-sectional view 1300E. At block 1216, an oxide reinforcing layer coating the Ti—Al in the vias is deposited. At block 1218, the oxide not in the vias is etched. At block 1220, the Ti—Al layer is patterned and etched to form a hinge layer component (e.g., a torsional hinge, a cantilever hinge, a spring tip, a raised electrode, etc.). The cross-sectional view 1300F of FIG. 13F shows the result of blocks 1216, 1218, and 1220. As shown in the cross-sectional view 1300F, some oxide 1307 from block 1218 may remain after etching at block 1220. Also, the shape of the hinge layer metal 1306 in FIG. 3F (the Ti—Al layer noted in block 1214) may vary depending on the patterning and etching of block 1220.

In the cross-sectional view 1300F of FIG. 13F, the via 1308 has been created by depositing, patterning, and etching various layers of materials. Example layers include the stack of metals 1302, the first sacrificial spacer via layer 1304, the hinge layer metal 1306, the oxide 1307, and the via 1308. In some examples, the thickness 1305A of the hinge layer metal 1306 may be 100-1000 Angstroms, and the oxide 1307 may have a thickness 1305B of approximately 3000 Angstroms. The oxide 1307 reinforces the hinge layer metal and/or related vias and provides support for the mirror of a MEMS device. In some examples, the oxide 1307 may be deposited through plasma-enhanced chemical vapor deposition (PECVD) in one example after the deposition of hinge layer metal 1306. In some examples, the oxide 1307 is removed from the top of the hinge layer metal 1306. In some examples, the oxide 1307 may remain only at the bottom and sidewall of the via 1308. In some examples, oxide etching is based on a fluorine-based plasma. In such examples, the fluorine-based plasma is highly selective to oxide 1307 over hinge layer metal 1306 so little to none of the hinge layer metal 1306 is removed.

In some examples, the stack of metals 1302 may include metals, metal alloys, a substrate, or a components of an anti-reflective coating (ARC) film stack. These layers have been deposited, patterned, and etched to form the structure shown in FIG. 13F. In some examples, metal layers may include titanium oxide, titanium nitride, and/or aluminum. In some examples, the stack of metals 1302 may be a complementary metal-oxide semiconductor (CMOS) substrate, which may sit on a substrate of intermetal dielectric (IMD) oxide (not shown). In some examples, the stack of metals 1302 may be built on top of a multi-layer transistor layout that includes traditional semiconductor source/drains, polysilicon gates, contacts, poly-metal dielectric, and multiple levels of interconnect metal isolated with inter-metallic dielectrics (not shown in FIG. 1A). The transistor layout may provide signals for controlling the operation of the PLM. The first sacrificial spacer via layer 1304 may be any suitable sacrificial material that is removed during a later processing step to release the MEMS device. The first sacrificial spacer via layer 1304 may be patterned and/or etched to produce the shape shown in FIG. 13F. The first sacrificial spacer via layer 1304 may be a photoresist or carbon rich film. in some examples, the material for the hinge layer metal 1306 may be deposited on portions of the first sacrificial spacer via layer 1304.

In the cross-sectional view 1300G of FIG. 13G, a non-photoactive organic polymer 1310 has been deposited on the structure of FIG. 13F. The non-photoactive organic polymer 1310 may be a spin-on carbon (SOC), which is a type of organic spin-coated polymer. The non-photoactive organic polymer 1310 may be a methacrylate polymer in some examples. As shown in FIG. 13G, the via 1308 may be filled with the non-photoactive organic polymer 1310. Other organic spin-coated polymers may be used in some examples.

In some examples, the non-photoactive organic polymer 1310 is deposited and spun for a certain target thickness. In some examples, the non-photoactive organic polymer 1310 is baked to cure it. In one example, the non-photoactive organic polymer 1310 may be baked at 180-220° Celsius (C.). In one example, the non-photoactive organic polymer 1310 is baked at 175-185° C. The non-photoactive organic polymer 1310 may become rigid after baking. As seen in FIG. 13G, due to the deposition and baking process, the non-photoactive organic polymer 1310 may have a divot 1312 after it has cured. In some examples, the divot 1312 may be flattened.

In some examples, a second layer of non-photoactive organic polymer is deposited. For example, a second sacrificial spacer via layer 1322 of the non-photoactive organic polymer may be deposited on non-photoactive organic polymer 1310 as in In the cross-sectional view 1300H of FIG. 13H. In one example, the second sacrificial spacer via layer 1322 may have a thickness 1323A between 1,000 and 10,000 Angstroms. A dashed line 1324 shows an approximate boundary between the first layer of non-photoactive organic polymer 1310 and the second sacrificial spacer via layer 1322. After the first layer of non-photoactive organic polymer 1310 is baked and cross linked, the second sacrificial spacer via layer 1322 may be deposited. The second sacrificial spacer via layer 1322 fills the divot 1312 and has a flat upper surface. After the second sacrificial spacer via layer 1322 is deposited, the structure of FIG. 13H is baked and cross linked to harden the second sacrificial spacer via layer 1322. In some examples, the structure is baked at 180-220° C. In some examples, the second sacrificial spacer via layer 1322 has a thickness 1323A that is thicker than the thickness 1323B of non-photoactive organic polymer 1310. If a divot occurs at the top of second sacrificial spacer via layer 1322, it may be a small divot that does not substantially affect the flatness of the mirror.

In the cross-sectional view 1300I of FIG. 13I, the resulting structure after the second sacrificial spacer via layer 1322 and non-photoactive organic polymer 1310 have been etched is represented. In this example, the second sacrificial spacer via layer 1322 and the non-photoactive organic polymer 1310 etch at the same rate because they are the same material. Therefore, no dome structure is present after etching such as the photoresist example described above. Rather, the top surface of non-photoactive organic polymer 1310 in via 1308 is flat. Therefore, flat structures may be created on top of non-photoactive organic polymer 1310 in subsequent processing steps. In an example, a mirror for a MEMS device may be created using the structure of FIG. 13I.

At block 1222 of the MEMS device fabrication method 1200, the result of block 1220 is coated with a sacrificial layer (e.g., of photoresist polymer). At block 1224, the resist layer is patterned using photolithography masks with via holes, including elongated via holes. At block 1226, an aluminum alloy that covers the sacrificial layer and the via sidewalls formed during block 1224 is deposited. The Ti—Al layer makes electrical contact with the TiN layer at the bottom of the via formed during block 1224. At block 1228, a mirror is patterned and etched.

FIGS. 13J to 13M show cross-sectional views 1300J, 1300K, 1300L, and 1300M showing mirror fabrication steps such as those in blocks 1222, 1224, 1226, and 1228. In FIG. 13J, the stack of metals 1302, the first sacrificial spacer via layer 1304, the hinge layer metal 1306, the oxide 1307, the via 1308, and non-photoactive organic polymer 1310 are represented. In some examples, the non-photoactive organic polymer 1310 is deposited and processed in two layers. In FIG. 13J, the second sacrificial spacer via layer 1322 has been added to the structure of FIG. 13I. The second sacrificial spacer via layer 1322 is deposited onto hinge layer metal 1306 and the non-photoactive organic polymer 1310.

In FIG. 13K, mirror vias 1324A and 1324B have been created in the second sacrificial spacer via layer 1322. For examples, the second sacrificial spacer via layer 1322 may be patterned and etched to create the mirror vias 1324A and 1324B. The mirror vias 1324A and 1324B are the structural connection from hinge layer metal 1306 to a mirror 1330 of the MEMS device as in FIG. 13L. In some examples, the material for mirror vias 1324A and 1324B may be deposited onto hinge layer metal 1306 using any suitable method. In some examples, the material for mirror vias 1324A and 1324B is an organic polymer. The mirror vias 1324A and 1324B may be between 0.3 and 6.0 micrometers deep (e.g., the via height 1328), and may also have a via diameter 1326 between 0.3 and 6.0 micrometers. In different examples, the mirror vias 1324A and 1324B may be deep filled mirror vias and may be partially or completely filled.

In FIG. 13L, a mirror 1330 is added to the structure of FIG. 13K. After the mirror vias 1324A and 1324B are created, mirror material (such as a metal) for the mirror 1330 is deposited on the second sacrificial spacer via layer 1322 and the mirror vias 1324A and 1324B. In some examples, the mirror 1330 may be a metal such as aluminum. The mirror 1330 may have a thickness 1332 between 500 and 5000 Angstroms. In the example of FIG. 13L, the mirror 1330 has a flat supper surface, in part, because the second sacrificial spacer via layer 1322 has a flat upper surface. The second sacrificial spacer via layer 1322 has a flat upper surface because there is no dome or divot (e.g., divot 1312) in the non-photoactive organic polymer 1310

In FIG. 13M, the sacrificial planarization materials and spacer materials (e.g., the first sacrificial spacer via layer 1304, the non-photoactive organic polymer 1310, and the second sacrificial spacer via layer 1322) have been removed. Removing these materials releases the final MEMS device. Once released, the hinge layer metal 1306 and the mirror 1330 may move freely during device operation (assuming the hinge layer metal 1306 is part of a hinge). Sacrificial materials and spacer materials may be removed using any suitable techniques, such as ashing, dry etching, or wet etching. After removal of the sacrificial materials, the mirror may move vertically. In some examples, after removal of the sacrificial materials, a corner of a mirror may tilt away from the plane of the MEMS device.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. A microelectromechanical system (MEMS) device comprising:
a hinge layer;
a second layer; and
an elongated via coupled between the hinge layer and the second layer.

2. The MEMS device of claim 1, wherein the second layer is a mirror layer.

3. The MEMS device of claim 1, wherein the second layer is an electrode layer including an electrode, the elongated via coupling the electrode and the hinge layer.

4. The MEMS device of claim 3, wherein the electrode is a bias electrode.

5. The MEMS device of claim 4, wherein the hinge layer includes a spring tip, the elongated via coupling the bias electrode and the spring tip.

6. The MEMS device of claim 4, wherein the hinge layer includes a hinge, the elongated via coupling the bias electrode and the hinge.

7. The MEMS device of claim 3, wherein the hinge layer includes a raised electrode, the elongated via coupling the raised electrode and the electrode.

8. The MEMS device of claim 7, wherein the elongated via has an elongation orientation parallel to the raised electrode.

9. The MEMS device of claim 1, wherein the elongated via is a first elongated via, the MEMS device comprises a second elongated via, the hinge layer includes a raised electrode, the first elongated via is a mirror via, the second elongated via is a spring tip via, the mirror via is spaced from a first side of the raised electrode by 0.125 um up to 0.15 um, and the spring tip via is spaced from a second side of the raised electrode by 0.15 um up to 0.175 um.

10. The MEMS device of claim 1, wherein the elongated via has a hollow elongated cylinder shape.

11. The MEMS device of claim 1, wherein the elongated via has an aspect ratio of elongation of at least 1.5.

12. A microelectromechanical system (MEMS) device comprising:
a mirror layer;
an electrode layer;
a hinge layer;
a mirror via coupling the mirror layer and the hinge layer; and
an elongated via coupling the hinge layer and the electrode layer.

13. The MEMS device of claim 12, wherein the electrode layer includes an electrode, the hinge layer includes a torsion hinge, the elongated via coupling the torsion hinge and the electrode.

14. The MEMS device of claim 12, wherein the electrode layer includes an electrode, the hinge layer includes a spring tip, the elongated via coupling the spring tip and the electrode.

15. The MEMS device of claim 12, wherein the electrode layer includes an electrode, the hinge layer includes a raised electrode, the elongated via coupling the raised electrode and the electrode.

16. The MEMS device of claim 13, wherein the mirror via is an elongated mirror via.

17. A microelectromechanical system (MEMS) device comprising:
a mirror layer;
an electrode layer including a first electrode and a second electrode spaced from the first electrode;
a hinge layer including a hinge;
an elongated via coupling the hinge and the mirror layer; and
a hinge via coupling the hinge and the first electrode.

18. The MEMS device of claim 17, wherein the hinge via is elongated.

19. The MEMS device of claim 17, wherein the hinge layer includes a spring tip, and the MEMS device further comprises an elongated spring tip via coupling the spring tip and the first electrode, wherein the first electrode is a bias electrode.

20. The MEMS device of claim 17, wherein the hinge layer includes a raised electrode, and the MEMS device further comprising an elongated electrode via coupling the raised electrode and the second electrode.
